(19) United States
(12) Patent Application Publication
(10) Pub. No.: US 2024/0409705 A1
(43) Pub. Date: Dec. 12, 2024

(54) DECONTAMINATION BATH AND METHOD FOR DECONTAMINATING A PLASTIC ARTICLE

(71) Applicant: SMART COLORING GMBH, Aachen (DE)

(72) Inventor: Bernd Robertz, Aachen (DE)

(21) Appl. No.: 18/697,077

(22) PCT Filed: Oct. 4, 2022
(86) PCT No.: PCT/EP2022/077608

§ 371 Date: Mar. 29, 2024

(30) Foreign Application Priority Data
Oct. 7, 2021 (EP) 21201355.1

(51) Int. Cl. C08J 11/06; B01D 11/02; B09B 3/35; B09B 3/80; B09B 101/75; B29B 17/02

(52) U.S. Cl. CPC C08J 11/06; B01D 11/0288; B09B 3/35; B09B 3/80; B29B 17/02; B09B 2101/75; B29B 2017/0296; B29K 2023/06; C08J 2323/06; C08J 2423/08

(57) ABSTRACT

A decontamination bath for decontaminating plastic articles including a contaminant is provided, wherein the decontamination bath includes water, a non-polar organic solvent component, optionally an anionic and/or non-ionic surfactant, a resoiling inhibitor, and an alkaline agent or an acidic agent for adjusting the pH of the decontamination bath, wherein the amount of the non-polar organic solvent component in the decontamination bath is 0.1 wt % to 25 wt % based on the total weight of the decontamination bath, and wherein the decontamination bath comprise the alkaline agent and the pH of the decontamination bath is ≥8, or wherein the decontamination bath comprise the acidic agent and the pH of the decontamination bath is ≤6. A method for decontaminating a plastic article using the above decontamination bath is also provided.

### CROSS-REFERENCE TO RELATED APPLICATIONS

This application claims priority to PCT Application No. PCT/EP2022/077608, having a filing date of Oct. 4, 2022, based on EP Application No. 21201355.1, having a filing date of Oct. 7, 2021, the entire contents both of which are hereby incorporated by reference.

### FIELD OF TECHNOLOGY

The following relates to a decontamination bath for decontaminating plastic articles.

Furthermore, the following relates to a method for decontaminating a plastic article comprising a decontaminant.

### BACKGROUND

Plastic articles, such as packaging and containers, are widely used in daily life, since they are easy to manufacture, rather inexpensive and lightweight. However, the increasing use of plastic articles may also present a risk to the environment. Annual global plastic production has exploded over the past decades, going from around 1.5 million metric tons (MT) in 1950 to about 368 million MT in 2019. Thus, plastic pollution has become one of the most pressing environmental issues, mostly visible in developing nations, where garbage collection systems are often inefficient or nonexistent.

One possibility to reduce the environmental impact of plastic articles is recycling plastics. However, the use of post-consumer recycled plastic materials in sensitive areas such as food contact applications presents a challenge as the recycled plastic may comprise substances which present a health and safety risks for consumers. Contamination originated during the product's life cycle restricts the use of recycled plastic.

The contaminants in plastics may have various sources. During the production of the starting substances or the plastic article side products may form that may be incorporated into the plastic article. Furthermore, structure-providing constituents of plastic articles, as well as other additives such as antioxidants or UV-stabilizers may degraded during manufacture and use of the plastic article, thus leading to various different breakdown products. Furthermore, the use or misuse of the plastic article by the consumer and in particular the recycling process itself can also introduce many different contaminants into the recycled plastic. Typical recycling-related contaminants are mineral oil hydrocarbons, and bisphenols, as well as flavor compounds, oligomers, and other small organic molecules.

Another challenge for plastic recycling presents colored plastic articles. Even though coloring agents such as dyes or pigments for coloring the plastic articles are intentionally added to the plastic during manufacturing of the plastic article, coloring agents present a disadvantage in the recycling process. The plastic articles may only be recycled at great expense by separating the articles in an additional sorting process according to their color, after having separated the articles according to the kind of plastic/polymer, in order to achieve high quality colored recycled material. When colorful plastics are mixed during regranulation, recyclates with undesirable color tones (brown, grey, black) result, so that these recyclates can only be used to a very limited extent.

Alternatively to sorting the plastic according to the color, the coloring agent with the plastic may be chemically modified during the recycling process for example by strong oxidation or reduction processes such that the coloring agent loses its chromophoric property. However, the destroyed coloring agent remains in the plastic and thus limit the use of the recyclate. Although it is possible to dissolve the plastics in chemical recycling by dissolving the colored plastic in suitable solvents, the effort involved is considerable and the use of dissolving the plastic for recycling contradicts the idea of sustainability.

Accordingly, there is a need to improve the decontamination process of plastic articles in order to provide recyclates of high quality.

### SUMMARY

An aspect relates to a decontamination bath for decontaminating plastic articles comprising a contaminant, wherein the decontamination bath comprises
water,
a non-polar organic solvent component,
optionally an anionic and/or non-ionic surfactant,
a resoiling inhibitor, and
an alkaline agent or an acidic agent for adjusting the pH of the decontamination bath,
wherein the amount of the non-polar organic solvent component in the decontamination bath is 0.1 wt % to 25 wt % based on the total weight of the decontamination bath, and
wherein the decontamination bath comprise the alkaline agent and the pH of the decontamination bath is ≥8, or
wherein the decontamination bath comprise the acidic agent and the pH of the decontamination bath is ≤6.

It is a further aspect of embodiments of the invention to provide a method for decontaminating a plastic article, wherein the plastic article comprises a contaminant, wherein the contaminant is an organic molecule having a molecular weight Mw≤800 g/mol, comprising the step
a) exposing the plastic article to a decontamination bath for ≥1 minute,
wherein the decontamination bath has a temperature above a glass transition temperature T_{g} and below a melting temperature Tₘ and/or decomposition temperature of the plastic article and/or wherein the decontamination bath has a temperature ≥60° C. to ≤130° C., and wherein the decontamination bath is realized as above-described.

The decontamination bath and the method for decontaminating the plastic article according to embodiments of the present invention increases the quality of the recycled plastic. In particular when using the above-described decontamination bath and/or the above-described method, a color change of the recyclate towards brownish/greenish colors during drying of the recyclate, as can be observed for decontamination methods according to conventional art, can be prevented as well as unpleasant odors. When using a decontamination bath according to conventional art for extracting contaminants a potential problem is that the extraction of the contaminants is not efficient. Furthermore, drying of the decontaminated recyclate can lead to a color change of the recyclate. Without being bound to a specific theory it is believed that the decontamination process is based on the migration of the decontaminant out of the plastic article into the decontamination bath and that the affinity of the contaminates towards the decontamination bath is not as high for a decontamination bath according to conventional art compared to the decontamination bath according to embodiments of the present invention. The lower affinity of the contaminant towards the decontamination bath according to conventional art leads to the situation that the contaminant attaches itself again to the recyclate after migration out of the recyclate and affects a color change towards brownish/greenish colors of the recyclate during drying of the recyclates and/or to unpleasant odors.

### DETAILED DESCRIPTION

### Non-Polar Organic Solvent Component

The decontamination bath comprises in an amount 0.1 wt % to 25 wt %, for example, 1 wt % to 15 wt %, and, as a further example, 3 wt % to 10 wt %, based on the total weight of the decontamination bath the non-polar organic solvent component.

In embodiments, the non-polar organic solvent component may be a non-polar organic solvent or mixture thereof, wherein the non-polar organic solvent may be free of heteroatoms selected from the group comprising O, F, N in embodiments. In an embodiment, the non-polar organic solvent may be free of heteroatoms selected from the group comprising O, F, N, Br, I, Cl, S, P. In an embodiment, the non-polar organic solvent may be a hydrocarbon. In an embodiment, the non-polar organic solvent may be liquid at 23° C.

According to an embodiment of the invention the non-polar organic solvent component is selected from aromatic non-polar solvents, aliphatic non-polar solvents, and mixtures thereof. Aliphatic non-polar solvents and mixtures of aliphatic non-polar solvents may be desired in embodiments.

With regard to the aliphatic non-polar solvent and according to an embodiment of the invention, the aliphatic non-polar solvent may be selected from straight, branched, saturated, unsaturated, and/or cyclic C₅ to C₁₆ aliphatic hydrocarbons.

With regard to the aromatic non-polar solvent and according to an embodiment of the invention, the aromatic non-polar solvent may be selected from C₁ to C₅-alkyl substituted benzene, C₂-alkyl substituted benzene, Xylol, C₃-alkyl substituted benzene, 1,3,5-trimethylbenzene, 1-ethyl-4-methylbenzene, prop-1-en-2-ylbenzene, propan-2-ylbenzene, propyl benzene, for example, C₃-alkyl substituted benzene in an embodiment.

As already mentioned, aliphatic non-polar solvents and mixtures of aliphatic non-polar solvents may be used in embodiments. In this regard and according to an embodiment of the invention, the non-polar organic solvent component consists of straight, branched, saturated, unsaturated, and/or cyclic C₅ to C₁₆ aliphatic hydrocarbons.

Furthermore, it was found that the quality of the recyclate is increased, when using hydrocarbons with lower molecular weight. In this regard and according to an embodiment of the invention, the non-polar organic solvent component consists of straight, branched, saturated, unsaturated and/or cyclic C₇ to C₉ aliphatic hydrocarbons or mixture thereof, or the non-polar organic solvent component is a petroleum fraction having a boiling range of 100° C. to 140° C. In embodiments, the petroleum fraction may be free of aromatic compounds and/or may consist of aliphatic hydrocarbons.

Anionic and/or Non-Ionic Surfactant

The decontamination bath optionally comprises the anionic and/or non-ionic surfactant. It was found that the quality of the recyclate is increased by having an anionic and/or non-ionic surfactant in the decontamination bath. Without being bound to a specific theory it is believed that the increased miscibility of the non-polar organic solvent component with water effected by the anionic and/or non-ionic surfactant increases the affinity of the contaminant to the decontamination bath and thus increases decontamination efficiency.

According to an embodiment of the invention, the decontamination bath comprises the anionic and/or non-ionic surfactant in an amount of 0.01 wt % to 10 wt %, for example, 0.05 wt % to 5 wt %, and as a further example, 0.1 wt % to 3 wt %, based on the total weight of the decontamination bath. In an embodiment, a mixture of an anionic and non-ionic surfactant may be used.

With regard to the non-ionic surfactant, in embodiments the non-ionic surfactant may be selected from the group comprising aromatic esters, aromatic and non-aromatic carboxylic acid esters, ethyl acrylate, fatty acid esters, alkoxylated, for example, ethoxylated or ethoxylated and propoxylated fatty acid esters, alkoxylated, for example, ethoxylated or ethoxylated and propoxylated fatty acids, poly oxyethylated compounds derived from sorbitol and oleic acid, polysorbate 20, polysorbate 40, polysorbate 60, polysorbate 65, polysorbate 80, polymers that are fatty acid-based with a non-ionic group per molecule, acrylate-copolymers, acrylate/styrene copolymers, fatty acid derivatives, polyalkoxylate, and for example, 2-(2-butoxy-ethoxy)ethanol and, as a further example, isotridecanolethoxylate.

According to an embodiment, the aromatic ester that may be used as non-ionic surfactant is selected from benzoic acid benzyl esters, naphthalic acid benzyl esters, phthalic acid benzyl esters and/or isophthalic acid benzyl esters, mixed aromatic aliphatic esters comprising benzyl butyl phthalates, and aliphatic esters comprising benzoic acid butyl esters, phthalic acid dibutyl esters, and/or isophthalic acid dibutyl esters; and for example, benzoic acid benzyl ester, benzoic acid esters such as benzyl benzoate, alkyl benzoates such as methyl or ethyl benzoate, naphthalic acid esters, phthalic acid esters.

In an embodiment, the anionic surfactant may be selected from the group comprising alkaline salts of a sulfonic acid, wherein the sulfonic acid may be selected form the group comprising alkyl benzenesulfonic acid, alkyl naphtalenesulfonic acid, alkyl phthalic sulfonic acid, isophthalic sulfonic acid benzyl, and C₉-C₁₃-alkyl benzenesulfonic acid.

### Resoiling Inhibitor

The decontamination bath comprises the resoiling inhibitor. It was found that the quality of the recyclate is increased by the resoiling inhibitor in the decontamination bath. Without being bound to a specific theory it is believed that the resoiling inhibitor increases the affinity of the decontamination bath to the decontaminant and helps preventing, that the contaminant attaches itself to the recyclate again after migration out of the recyclate. The resoiling inhibitor may form a complex with the decontaminant having a higher solubility in the decontamination bath than the contaminant alone.

According to an embodiment of the invention, the decontamination bath comprises the resoiling inhibitor in an amount of 0.001 wt % to 10 wt %, for example, 0.1 wt % to 5 wt %, and, as a further example, 0.5 wt % to 1 wt %, based on the total weight of the decontamination bath. In an embodiment, the amount of resoiling inhibitor in the decontamination bath may be adjusted to the amount of decontaminant in the plastic article.

In an embodiment, the resoiling inhibitor is selected from the group comprising
polymeric resoiling inhibitors, in particular polyvinylpyrrolidone, derivatives of polyvinylpyrrolidone, such as poly(4-vinylpyridine-N-oxide) and/or polyvinylpyrrolidone-Betaine, copolymers formed of vinylpyrrolidone and vinylimidazole, copolymers formed of vinylpyrrolidone and Poly-4-vinylpyridine-N-oxide, sulfonates comprising an aromatic group, salts of polydiallyldimethylammonium, for example PolyDADMAC, copolymers of polydiallyldimethylammonium formed with acrylic and/or methacrylic acid, copolymers of polydiallyldimethylammonium formed with acrylamide and/or vinylpyrrolidone, saccharide/acrylate copolymers, polycarboxylic acids and copolymers, acrylate copolymers, polymeric carboxylic acid containing polyphosphates, amphiphilc block-copolymers, polyquaterniums; polyvinylimidazole and copolymers of polyvinylimidazole for example with polyviniylpyrrolidone;
ionic compounds comprising polymeric metasilicate anions such as waterglass;
phosphonates,
   dye transfer inhibitors comprising a combination of a) hydrocarbyl substituted pyridine or a polymer or oligomer including vinylpyridine monomer units and b) a hydrocarbyl sulfonic acid such as 2-acrylamido-2-methylpropane sulfonic acid monomer or a polymer formed from the monomer
surfactant-free colloid systems based on inorganic salts, such as Disodium metasilicate pentahydrate or colloid systems based on phosphates.

### Oxidizing Agent, Reducing Agents

As already mentioned, it is believed that the decontamination process is based on the migration of the decontaminant out of the plastic article into the decontamination bath. In order to enhance the decontamination process, in embodiments the decontamination bath may comprise an oxidizing agent, or a reducing agent. The oxidizing agent as well as the reducing agent may destroy the decontaminant. The destruction of the decontaminant can be accelerated or simplified by catalysts, e.g., applied to nanostructured fibers over a large area. Such catalysts are available, for example, from Nanofique Ltd. The oxidizing agent or the reducing agent may shift the equilibrium of the decontamination reaction towards the decontaminated plastic article in embodiments.

Exemplary oxidizing agents are selected from the group comprising a peroxide, peroxyacetic acid, hydrogen peroxide, peroxodisulfate, ozone, sodium percarbonate, sodium perborate, sodium percarbonate, m-nitrobenzolsulfonat, H₂SO₄, HNO₃, oxygen-containing anions (oxo anions) of transition metals in high oxidation states such as permanganate MnO₄⁻, KMnO₄, phosphate, oxygen difluoride fluorine, cryptone difluoride, dichromate Cr₂O₇²⁻, metal ions such as Ce₄⁺, noble metal ions such as those of silver and copper, anions of halo-oxygen acids such bromate BrO₃⁻, halogens, such as fluorine, chlorine, bromine and iodine, hypochlorite, sodium hypochlorite, sodium peroxodisulfate and/or potassium hypochlorite.

Exemplary reducing agents are selected from the groups comprising
hydrogen in combination with precious metal catalyst, for example, H₂/Ni, H₂/Pd, H₂/Pt, hydrides;
complex hydrides, for example, sodium hydride NaH, lithium aluminum hydride LiAlH₄, borohydride salts NaBH₄;
base metals, for example, Li, Na, Mg, Zn; low-valent nitrogen;
phosphorus and sulphur compounds, for example, amidine sulfonic acid, hydrogen sulfide, sodium sulfide, S₂—, Na₂S, sulfites, SO₂⁻³, sodium sulfite, sulfurous acid, sulfur dioxide, thiosulphate, sodium dithionite, sodium bisulfite, NaHSO₃, formamidine sulfinic acid, zinc hydroxylmethansulfinate, sodium hydroxy methane sulfinate also known as rongalite, thiourea dioxide also known as thiox, sulfonic acid and its derivatives, borohydride salts, sodium hydroxide, sodium carbonate, sodium bicarbonate, sodium oxide, and mixtures of sodium hydroxide and calcium oxide, sulfinic acid derivatives, borohydrides and/or REDULIT GIN;
sulfinic acid and sulfinic acid derivates, for example, aminoimino methansulfinsaure; and
glucose mixtures with dispersants.

According to an embodiment of the invention the amount of oxidizing agent or reducing agent in the decontamination bath may be at least 0.5 g/L, for example, at least 5 g/L, as a further example, at least 10 g/L, based on the volume of the decontamination bath. In an embodiment, the amount of oxidizing agent or reducing agent in the decontamination bath may be less than 25 g/L, for example, less than 20 g/L, as a further example, less than 15 g/L, based on the volume of the decontamination bath. In an embodiment, either the oxidizing agent or the reducing agent may be present in the decontamination bath—or in other words, the oxidizing agent and the reducing agent are not present in the decontamination bath at the same time.

### Metal Ions

According to an embodiment of the invention, the decontamination bath may be free of multitvalent metal ions, and for example, free of Al³⁺, Mg²⁺, Ca²⁺, Zn²⁺. It is believed that multivalent metal ions may form complexes with the decontaminant that have a decreased solubility in the decontamination bath and have the tendency to attach to the plastic article.

With regard to the oxidizing and reducing agent, in embodiments this may mean that metal-free oxidizing agents and metal-free reducing agents are desired, for example, organosulfur compounds as reducing agents and peroxides and hypochlorites as oxidizing agents.

In this regard and according to an embodiment of the invention, the decontamination bath may comprise a chelating agent. The chelating agent may chelate metal ions that are present in the decontamination bath. In an embodiment, the chelating agent may be selected from salts of ethylenediaminetetraacetic acid (EDTA), Ethylenediamine-N,N′-disuccinic acid (EDDS), Nitrilotriacetic acid (NTA), iminodisuccinic acid (IDS), polyaspartic acid, S,S-ethylenediamine-N,N′-disuccinic acid (EDDS), methylglycinediacetic acid (MGDA), and L-Glutamic acid N,N-diacetic acid, tetrasodium salt (GLDA).

pH

To enable the decontamination process, the pH of the decontamination bath is alkaline or acidic. In a first alternative the decontamination bath has a pH≥8, for example, ≥10, as a further example, about ≥11, and wherein the pH of the decontamination bath is adjusted by adding the alkaline agent, for example, NaOH. The use of organic bases such as ammonia in order to adjust the pH is also possible.

Alternatively, the decontamination bath has a pH about ≤6, for example, ≤4, as a further example, about ≤3, and wherein the pH of the decoloring bath is adjusted by adding the acid agent, for example, HCl. The use of organic acids such as formic acid in order to adjust the pH is also possible.

In an embodiment, the pH of the decontamination bath may be pH≥8—or in other words, the decontamination bath may be an alkaline decontamination bath.

### Method for Decontamination the Plastic Article

As already mentioned, embodiments of the invention also relate to the method for decontaminating the plastic article, wherein the plastic article comprises a contaminant, wherein the contaminant is an organic molecule having a molecular weight Mw≥800 g/mol, comprising the step
a) exposing the plastic article to a decontamination bath for 1 minute, wherein the decontamination bath has a temperature above a glass transition temperature T_{g} and below a melting temperature Tₘ and/or decomposition temperature of the plastic article and/or wherein the decontamination bath has a temperature 60° C. to ≤130° C., and wherein the decontamination bath is realized as above-described.

According to an embodiment the exposed plastic article does not entirely dissolve in the decontamination bath and/or the plastic article is solid during exposure to the decontamination bath. In other words, the decontamination process does not involve a complete dissolution of the plastic article in the decontamination bath. Instead during the decontamination process in embodiments, the decontaminant may migrate out of the solid plastic article and into the decontamination bath.

### Plastic Article

In general, the plastic article may be any plastic article comprising any plastic or any mixture of plastics and may be selected according to the use of the plastic article. In an embodiment, the plastic article may be a thermoplastic and/or a thermoplastic elastomer. In an embodiment, the plastic article comprises at least 0.001 wt % of a polar component, based on the weight of the plastic article. It is believed that a wettability of the plastic article is increased and therefore the polar component facilitates decontamination of the plastic article from the decontaminant. Accordingly, in embodiments the plastic article comprises at least 0.1 wt % of the polar component, based on the weight of the plastic article, wherein the polar component is a polar polymer, a polar compound and/or a blend of polar polymers and/or polar compounds, wherein the polar component has at least 5 wt % of heteroatoms based on the molecular weight of the polar component, and wherein heteroatoms are any atoms except C and H atoms.

The polar component may be a polar polymer or mixtures of polar polymers, a polar compound or mixtures of polar compounds, or a mixture of polar polymers and polar compounds. The polar polymer as well as the polar compound comprise at least 5 wt % of heteroatoms based on the molecular weight of the polar polymer or the polar compound, respectively. Thus, these substances have a significant dipole moment and are polar.

It is possible that the plastic article comprises up to 99.999 wt % of a non-polar polymer or of mixtures of non-polar polymers, such as polyethylene (PE), polypropylene (PP), polybutylene (PB). According to an embodiment of the invention the plastic article comprises ≤99.9 wt %, for example, ≤99.5 wt %, as a further example, ≤98 wt %, and as an even further example, ≤95 wt. % of a non-polar polymer or mixtures of non-polar polymers, based on the weight of the plastic article, wherein the non-polar polymer has a molecular weight Mw≥1000 g/mol, for example, Mw≥1200 g/mol, as a further example, Mw≥1500 g/mol and has less than 5 wt % of heteroatoms based on the molecular weight of the non-polar polymer, wherein heteroatoms are any atoms except C and H atoms. Furthermore, in embodiments, the plastic article comprises in addition to the non-polar polymer at least 0.001 wt %, for example, at least 1 wt %, as a further example, at least 2 wt %, and as an even further example, at least 3 wt % of the polar component, based on the weight of the plastic article. The polar component can be the polar polymer, the polar compound or mixtures of polar polymers and/or polar compounds.

In embodiments, the polar polymer may have a molecular weight Mw≥1000 g/mol, for example, Mw≥1200 g/mol, as a further example, Mw≥1500 g/mol and has at least 5 wt % of heteroatoms based on the molecular weight of the polar polymer, wherein heteroatoms are any atoms except C and H atoms. In an embodiment, the heteroatom may be selected from the group comprising O, N, S, P, F, Cl, Br, and I. In embodiments, the polar compound may have a molecular weight Mw≤1000 g/mol, for example, Mw≤900 g/mol, as a further example, Mw≤800 g/mol and has at least 5 wt % of heteroatoms based on the molecular weight of the polar compound, wherein heteroatoms are any atoms except C and H atoms. In an embodiment, the heteroatom may be selected from the group comprising O, N, S, P, F, Cl, Br, and I.

According to an embodiment of the invention, the plastic article comprises less than 16 wt %, for example, less than 10 wt %, as a further example, less than 5 wt % of the polar compound, based on the weight of the plastic article. Since the polar compound, which in embodiments may have a molecular weight Mw≤1000 g/mol, for example, Mw≤900 g/mol, as a further example, Mw≤800 g/mol, may affect the physical properties of the plastic article when used in high amounts, the amount of polar compound in the plastic article in embodiments is not higher than 25 wt %, based on the weight of the plastic article.

### Mw of Polar Polymer and Non-Polar Polymer

For polymers the individual polymer chains rarely have exactly the same degree of polymerization and molar mass, and there is a distribution around an average value (molecular weight distribution (MWD)). To this regard, the molecular weight of the polar polymer and non-polar polymer is given with respect to the Mass average molar mass or Mw (also commonly referred to as weight average or Weight Average Molecular Weight (WAMW)).

The mass average molecular mass can be determined by gel permeation chromatography, static light scattering, small angle neutron scattering, X-ray scattering, and/or sedimentation velocity. Furthermore, in case the distribution is known, the mass average molecular mass can be calculated by

M_{w}=ΣᵢNᵢMᵢ²/ΣᵢNᵢMᵢ

where Nᵢ is the number of molecules of molecular mass Mᵢ. In an embodiment, the mass average molecular mass may be determined by gel permeation chromatography.

### Polar Polymer

The polar polymer or mixture thereof may be selected from the group comprising:
polyacrylate with methyl (polymethylacrylate), ethyl (polyethylacrylate), propyl (polypropylacrylate), or butyl (polybutylacrylate),
polymethacrylate with methyl (polymethylmathacrylate), ethyl (polyethylmethacrylate), propyl (polypropylmethacrylate), or butyl (polybutylmethacrylate),
copolymers of acrylic and methacrylic esters including, among others, tert-Butyl (meth)acrylate, pentyl(meth)acrylate and 2-ethylhexyl(meth)acrylate; (Meth)acrylates derived from unsaturated alcohols, for example, oleyl(meth)acrylate, 2-propynyl(meth)acrylate, allyl(meth)acrylate, vinyl(meth)acrylate;
aryl(meth)acrylates polymers, for example, benzyl(meth)acrylate polymers or phenyl(meth)acrylate polymers, the aryl radicals each being unsubstituted or up to four times substituted;
cycloalkyl(meth)acrylates polymers, for example 3-vinylcyclohexyl(meth)acrylate polymers, bornyl (meth)acrylate polymers;
hydroxylalkyl (meth)acrylates polymers, for example, 3-hydroxypropyl (meth)acrylate polymers, 3,4-dihydroxybutyl(meth)acrylate polymers, 2-hydroxyethyl(meth)acrylate polymers, 2-hydroxypropyl(meth)acrylate polymers;
glycol di(meth)acrylates polymers, for example, 1,4-butanediol (meth)acrylate polymers;
(meth)acrylates of ether alcohols polymers, for example, tetrahydrofurfuryl (meth)acrylate polymers, vinyloxyethoxyethyl(meth)acrylate polymers;
polymers of amides and nitriles of the (meth)acrylic acid, for example, N-(3-dimethylaminopropyl)(meth)acrylamide polymers, N-(diethylphosphono)(meth)acrylamide polymers, 1-methacryloylamido-2-methyl-2-propanol polymers;
polymers of sulfur-containing methacrylates, for example, ethylsulfinylethyl(meth)acrylate, 4-thiocyanatobutyl(meth)acrylate polymers, ethylsulfonylethyl(meth)acrylate polymers, thiocyanatomethyl(meth)acrylate polymers, methylsulfinylmethyl(meth)acrylate polymers, bis((meth)acryloyloxyethyl)sulfide polymers;
polyhydric (meth)acrylates, for example, trimethyloylpropanetri(meth)acrylate polymers;
acrylonitrile polymers;
vinyl ester polymers, for example, vinyl acetate polymers;
styrene polymers, substituted styrenes polymers with an alkyl substituent in the side chain, for example, α-methylstyrene and α-ethylstyrene, substituted styrenes polymers with an alkyl substituent on the ring, for example, vinyl toluene, and p-methylstyrene, halogenated styrene polymers, for example, monochlorostyrene polymers, dichlorostyrene polymers, tribromostyrene polymers and tetrabromostyrene polymers;
heterocyclic vinyl polymers, for example, 2-vinylpyridine polymers, 3-vinylpyridine polymers, 2-methyl-5-vinylpyridine polymers, 3-ethyl-4-vinylpyridine polymers, 2,3-dimethyl-5-vinylpyridine polymers, vinylpyrimidine polymers, vinylpiperidine polymers, 9-vinylcarbazole polymers, 3-vinylcarbazole polymers, 4-vinylcarbazole polymers, 1-vinylimidazole polymers, 2-methyl-1-vinylimidazole polymers, N-vinylpyrrolidone polymers, 2-vinylpyrrolidone polymers, N-vinylpyrrolidine polymers, 3-vinylpyrrolidine polymers, N-vinylcaprolactam polymers, N-vinylbutyrolactam polymers, vinyl oxolane polymers, vinyl furan polymers, vinyl thiophene polymers, vinylthiolane polymers, vinylthiazoles and hydrogenated vinylthiazoles polymers, vinyloxazoles and hydrogenated vinyloxazoles;
polymers of vinyl and isoprenyl ethers;
maleic acid polymers, for example, maleic anhydride polymers, methyl maleic anhydride polymers, maleimide polymers, methyl maleimide;
copolymers of ethylene and/or propylene with acrylic esters, for example, polyethylen-block-co-polymethylmethacrylat, polypropylen-block-co-polymethylmethacrylat, and ethylene-acrylate copolymers;
aliphatic and/or aromatic polyesters, for example, hydroxyl-functional dendritic polyesters, polycaprolactone, polyethylenterephthalate (PET), polyethylene naphthalate (PEN), polyethylene furanoate (PEF), polytrimethylenterephthalat (PTT), polybutylenterephthalat (PBT), glycolized polyglycolterephthaltat (G-PET), amorphous polyethylenterephthalat (A-PET), polyesters of terephthalic acid, polyspiro-diol-terephthalate, polypentaspiroglycol-terephthalate (PSG), polycyclohexylenedimethylene-terephthalate (PCT), Polyethylenfuranoate (PEF), Polyethylennaphthylat, polyester based copolymer including a dicarboxylic acid-derived residue including a residue derived from an aromatic dicarboxylic acid and a diol-derived residue including a residue derived from 4-(hydroxymethyl)cyclohexylmethyl-4′-(hydroxy-methyl)cyclohexane carboxylate, polyester based copolymer including a dicarboxylic acid-derived residue including a residue derived from an aromatic dicarboxylic acid and a diol-derived residue including a residue derived from 4,4-(oxybis(methylene)bis) cyclohexane methanol;
polycarbonate (PC), 2,2-Bis-(4-hydroxyphenyl)-propan (Bisphenol A) polycarbonate, 2,2-Bis-(4-hydroxyphenyl)-butan (Bisphenol B) polycarbonate, 1,1-Bis(4-hydroxyphenyl)cyclohexan (Bisphenol C) polycarbonate, 2,2′-Methylendiphenol (Bisphenol F) polycarbonate, 2,2-Bis(3,5-dibrom-4-hydroxyphenyl)propan (Tetrabrombisphenol A) polycarbonate und 2,2-Bis(3,5-dimethyl-4-hydroxyphenyl)propan (Tetramethylbisphenol A) polycarbonate, bisphenol S polycarbonate, dihydroxydiphenylsulfid polycarbonate, tetramethylbisphenol A polycarbonate, 1,1-Bis(4-hydroxyphenyl)-3,3,5-trimethylcyclohexane (BPTMC) polycarbonate, 1,1,1-Tris(4-hydroxyphenyl)-ethane (THPE) polycarbonate;
aliphatic polyamide (PA), for example, PA 6 based on polycaprolactam, PA 6.6 based on 1,6-hexamethylendiamin and adipic acid, PA 6.66 based on caprolactam, co-polymer of hexamethylendiamin and adipic acid, PA 66.610 based on hexamethylendiamin, copolymer of adipic acid and sebaic acid, PA 4.6, PA10, PA 12 and PA copolymers;
polyurethane (PU),
polar-copolymere, maleic anhydride-olefin copolymer;
polyalkylenoxide, polyalkylene block copolymer, propylenoxide-ethylenoxide copolymer, (m)ethylene acrylate-maleic anhydride copolymer;
polar-terpolymere, for example, reactive terpolymers of ethylene, acrylic ester and maleic anhydride, or ethylene, methacrylic ester and maleic anhydride, or ethylene, acrylic esters and glycidyl methacrylate, or ethylene, methacrylic esters and glycidyl methacrylate, or ethylene, (meth)acrylic esters and methyl (methyl(meth)acrylate), ethyl (ethy(meth)acrylate), propyl (propyl(meth)acrylate), or butyl (butyl(meth)acrylate), polyamide, polyester-polyamides, or butyl (butyl(meth)acrylate), polyether-polyamide copolymers;
polar polymer blends, for example, polycarbonate/polyethylenterephthalat blends (PC/PET blends), polycarbonate/polybutyleneterephthalate blends (PC/PBT blends), blends of polycyclohexylene dimethylene terephthalate copolymer, blends of poly(butylene-adipate-terephthalate);
polyacrylnitril and polyacrylnitril-copolymers, for example, poly acrylonitrile butadiene styrene (ABS), poly styrene-acrylonitrile;
polystyrene and polystyrene copolymers, for example, styrene/butadiene co-polymer (SBR), poly styrene-isoprene-styrene (SIS), poly(glycidyl methacrylate) grafted sulfonamide based polystyrene resin with tertiary amine;
ethylene-vinyl acetate;
polyether, for example, polyethyleneglycol, polyethyleneglycol with at least one fatty acid coupled to the polyethyleneglycol, terminating functional groups such NH₂-terminated polyethers;
functionalized polyacrylamide polymers, copolymers and terpolymers, for example, poly(2-acrylamido-2-aminopropionicacid) (polyAMPA), poly(2-acrylamido-2-amino propane sulfonic acid), poly(N-isopropylacylamide (polyPNIPAM); poly (amidoamine-co-acrylic acid) copolymer, poly(N,N-dimethylacrylamide-co-sodium acrylate), poly(acrylamide-co-sodium acrylate)/poly(ethylene glycol) semi-IPN, poly(acrylamide-co-sodium 4-styrenesulfonate), poly(acrylamide-co-sodium 4-styrenesulfonate)/poly(ethylene glycol) semi-IPN, poly(acrylamide-co-sodium methacrylate), poly(acrylamide-co-sodium methacrylate)/poly(ethylene glycol) semi-IPN, and/or poly(N-isopropylacrylamide-co-acrylic acid) and poly(acrylamide-co-acrylic acid;
poly(ether sulfones)/poly(ethyleneimine) (PES/PEI);
polyvinylpyrrolidone, for example, poly(N-vinyl-2-pyrrolidone), poly(N-vinyl-2-pyrrolidone-co-acrylonitrile) treated with hydroxylamine-hydrochloride
polyvinyl alcohol; and/or
poly(1-naphthylamine)-camphorsulphonic acid.

Other polar polymers of amorphous co-polyester, which can be used are known under the tradename Akestra 90, 100 and 110. The above named synthetic polar-polymers may be used alone or in a mixture of two or more.

With regard to hydroxyl-functional dendritic polyesters that can be suitable used as a polar polymer, these molecules may be produced using polyalcohol cores, hydroxy acids and technology based on captive materials. The dendritic structures may be formed by polymerization of the particular core and 2,2-dimethylol propionic acid (Bis-MPA). The hydroxyl-functional dendritic polyesters may be known under the trade name Boltom®. The following dendritic polymers may be used as non-limiting examples: Boltom® H20 16 terminal hydroxyl groups, nominal molecular weight of 1750 g/mol, Boltom® H2004 6 terminal hydroxyl groups, nominal molecular weight of 3100 g/mol, Boltom® H311 23 terminal hydroxyl groups, nominal molecular weight of 5300 g/mol, Boltom® P500 Formulated bimodal product with terminal hydroxyl groups, nominal molecular weight 1800 g/mol, Boltom® P1000 formulated bimodal product with terminal hydroxyl groups, nominal molecular weight 1500 g/mol, Boltom® U3000 modified with unsaturated fatty acid, nominal molecular weight 6500 g/mol, Boltom® W3000 modified with non-ionic groups and unsaturated fatty acid, nominal molecular weight 10000 g/mol.

With regard to the polyester based copolymers that can be suitable used as a polar polymers, these may further include but not limited to a dicarboxylic acid-derived residue including a residue derived from an aromatic dicarboxylic acid and a diol-derived residue including a residue derived from 4-(hydroxymethyl)cyclohexylmethyl-4′-(hydroxymethyl)cyclohexane carboxylate represented by the following chemical formula 1 and a residue derived from 4,4-(oxybis(methylene)bis) cyclohexane methanol represented by the following chemical formula 2.

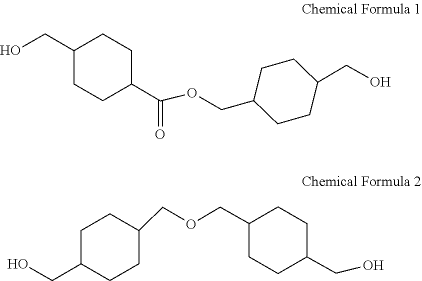 [SMILES: O=C(OCC1CCC(CO)CC1)C1CCC(CO)CC1 ; OCC1CCC(COCC2CCC(CO)CC2)CC1]

The compounds of chemical formula 1 and 2 can be copolymerized with aromatic dicarboxylic acid may be one or more selected from a group consisting of terephthalic acid, dimethyl terephthalate, cyclic dicarboxylic acid, isophthalic acid, adipic acid, azelaic acid, naphthalene dicarboxylic acid, and succinic acid.

The diol-derived residue of the copolymers may further include a residue derived from one or more other diols selected from a group consisting of 1,4-cyclohexane dimethanol, 1,2-propanediol, 1,3-propanediol, 1,4-butanediol, 2,2-dimethyl-1,3-propanediol, 1,6-hexanediol, 1,2-cyclohexanediol, 1,4-cyclohexanediol, 1,2-cyclohexane dimethanol, 1,3-cyclohexane dimethanol, 2,2-dimethylpropane-1,3-diol (neopentyl glycol), ethylene glycol, and diethylene glycol. A content of the diol derived residues of the residue derived from 4-(hydroxymethyl)cyclohexylmethyl 4′-(hydroxymethyl)cyclohexane carboxylate, the residue derived from 4,4-(oxybis(methylene)bis) cyclohexane methanol, and other diol-derived residues may be about 10 to 80 mol % based on 100 mol % of the dicarboxylic acid co-monomer.

The polar polymer may also comprise the polyester based copolymers used in a mixture with polyethylene terephthalate (PET). The mixture may consist of 1 to 99 wt % of PET and 1 to 99 wt % of the polyester based copolymers, in order that both components add up to 100 wt %. Additionally, or alternatively the compounds according to chemical formulas 1 and 2 may be used as co-monomers together with a further diol-component, e.g., ethylene glycol, in the preparation of the polyester based copolymers.

The polyester based copolymer may be prepared by reacting the dicarboxylic acid including the aromatic dicarboxylic acid with the diol including 4-(hydroxymethyl)cyclohexylmethyl 4′-(hydroxymethyl)cyclohexane carboxylate represented by chemical formula 1 and 4,4-(oxybis(methylene)bis) cyclohexane methanol represented by chemical formula 2 to perform an esterification reaction and a polycondensation reaction. In this case, other diols such as 1,4-cyclohexane dimethanol, ethylene glycol, diethylene glycol, or the like, as described above may be further reacted, such that a polyester based copolymer further including other diol-derived residues may be prepared.

With regard to the polyether, these may comprise but are not limited to compounds that contain at least one polyethyleneglycol moiety and at least one fatty acid moiety coupled to the polyethyleneglycol moiety. The polyethyleneglycol moiety may contain 10 to 25 ethyleneglycol repeating units. The fatty acid moieties may be saturated or unsaturated and may contain 10 to 30 carbon atoms, for example, 16 to 22 carbon atoms. Examples of these fatty acid moieties are oleate, laureate, stearate, palmitate and ricinoleate. A specific example may be ethoxylated sorbitan ester.

The ethoxylated sorbitan ester comprises a sorbitan group which is substituted by four polyethylene glycol substituents. In embodiments, the ethoxylated sorbitan ester may comprise 14 to 26 ethylene glycol repeating units, for example, 16 to 24 ethylene glycol repeating units, as a further example, between 18 and 22 repeating units. At least one of the ethylene glycol substituents in the ethoxylated sorbitan ester is connected via an ester bond to a fatty acid moiety. In an embodiment, at least two of the ethylene glycol substituents in the ethoxylated sorbitan ester are connected via an ester bond to a fatty acid moiety; for example, at least three of the ethylene glycol substituents may be connected via an ester bond to a fatty acid moiety. The fatty acid moieties may be saturated or unsaturated and may contain 10 to 30 carbon atoms, for example, 16 to 22 carbon atoms.

Examples of these fatty acid moieties are oleate, laureate, stearate and palmitate. In embodiments, most desired may be ethoxylated sorbitan esters comprising four polyethylene glycol substituents and wherein the ester comprises between 18 and 22 ethylene glycol repeating units and wherein three of the ethylene glycol substituents are connected to oleate, laurate or stearate groups.

Examples of ethoxylated sorbitan esters that can be used as polar-polymer are polyoxyethylene (20) sorbitane monolaurate, polyoxyethylene (20) sorbitane dilaurate, polyoxyethylene (20) sorbitane trilaurate, polyoxyethylene (20) sorbitane mono-oleate, polyoxyethylene (20) sorbitane di-oleate, polyoxyethylene (20) sorbitane tri-oleate, polyoxyethylene (20) sorbitane monostearate, polyoxyethylene (20) sorbitane distearate, polyoxyethylene (20) sorbitane tristearate, and polyoxyethylene (20) sorbitan monooleate, also known as Polysorbate 80 and E433.

Polysorbates are ethoxylated sorbitan fatty acid esters in the form of oily liquids. These non-ionic surfactants are used as wetting agents or as emulsifiers of the O/W type, for example, in cosmetics, pharmaceuticals, foods, cleaning agents and detergents. Well-known trade names include Tween, Scattics, Alkest and Canarcel. The different types of polysorbates differ in the fatty acid, the average number of polyoxyethylene units in the molecule and the degree of esterification. The two-digit number of the name of each polysorbate follows a certain scheme: The first number stands for the mainly esterified acid: 2=lauric acid, 4=palmitic acid, 6=stearic acid, 8=oleic acid, 12=isostearic acid. The second digit indicates the type of esterification: 0 for a monoester with 20 polyoxyethylene units, 1 for a monoester with 4 or 5 polyoxyethylene units and the number 5 stands for a triester with 20 polyoxyethylene units.

Polysorbate 80 is a polyoxyethylated compound derived from sorbitol and oleic acid. The hydrophilic groups of this non-ionic surfactant are polyethers, polymers of a total of 20 ethylene oxides. Other representatives from the group of polysorbates are for example: Polysorbate 20, Polysorbate 40, Polysorbate 60, and Polysorbate 65.

In an embodiment, the polar polymer may have a molecular weight Mw≥1000 g/mol, for example, Mw≥1200 g/mol, as a further example, Mw≥1500 g/mol.

Polar compound

The polar compound or mixtures thereof may be selected from the group comprising aliphatic acids CH₃—[CH₂]ₙ—COOH acids (n about ≥3), amino acids, carboxylic acid amide, hydroxyl acids, fatty acids, and their esters aliphatic or aliphatic/aromatic aldehydes and ketones, esters, pentaerythritol, pentaerythritol dimers, pentaerythritol trimers, pentaerythritol ester for example, carboxylic acid ester, benzoic acid esters comprising benzyl benzoat or phenyl benzoat, phenylether, alcohols and polyvalent alcohols, for example, glycerine, amines.

The carboxylic acid amide may comprise a compound according to formula C₂H₄(NHC(O)R³)₂, wherein R³ is a fatty acid moiety comprising 10-17 carbon atoms. The fatty acid moieties may be saturated or unsaturated. When the amount of carboxylic acid amide is too high the colored plastic article may show blooming. Blooming i.e., discolorations may be caused by phase separation of the plastic material's components. It may be caused by incompatibilities of the polar compound with the plastic basis material.

Pentaerythritol may comprise a compound according to formula C(CH₂OR)₄, wherein R may be H, or wherein R may be a fatty acid moiety comprising 5-8 carbon atoms. The fatty acid moieties can be saturated or unsaturated. R may be also another moiety like ether, amide and/or urethane. As Pentaerythritol Perstorp Charmor PM 40 may be used.

Furthermore, the polar compound may be an ether. The ether may comprise but not limited to compounds that contains at least one ethyleneglycol moiety and at least one fatty acid moiety coupled to the ethyleneglycol moiety.

Examples of compound that contains at least one ethyleneglycol moiety and at least one fatty acid moiety coupled to the polyethyleneglycol moiety include PEG 300-monostearate, PEG 400 monolaurate. The carboxylic acid ester may comprise a compound according to the following chemical formula 3:

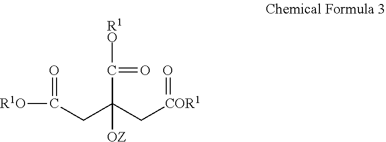

wherein R¹ is an alkyl group comprising 1-20 carbon atoms and Z is hydrogen or a group according to the formula C(O)R², wherein R² is an alkyl group comprising 1-20 carbon atoms. Rⁱ may be the same or different and is an alkyl group comprising 1-20 carbon atoms, for example, 1-15 carbon atoms, as a further example, 1-10 carbon atoms. In embodiments, R² is an alkyl group comprising 1-20 carbon atoms, for example, 1-10 carbon atoms, as a further example, 1-5 carbon atoms. Non-limiting examples of the carboxylic acid ester are triethylcitrate, tributylcitrate, trihexylcitrate, acetyltributylcitrate (ATBC; R¹═C₄H₉, Z═CH₃CO), propanoyltributylcitrate, acetyltrihexylcitrate and butanoyltriethylcitrate.

Furthermore, as polar compound 4-(hydroxymethyl)cyclohexylmethyl-4′-(hydroxymethyl)cyclohexane carboxylate represented by the chemical formula 1, 4,4-(oxybis(methylene)bis) cyclohexane methanol represented by the chemical formula 2, and mixtures thereof may be used:

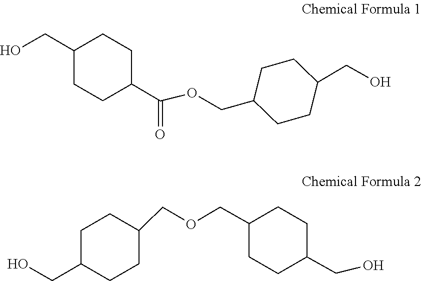 [SMILES: O=C(OCC1CCC(CO)CC1)C1CCC(CO)CC1 ; OCC1CCC(COCC2CCC(CO)CC2)CC1]

### Non-Polar Polymer

As already mentioned above, the plastic article may comprise the non-polar-polymer or mixtures of non-polar polymers. In connection to this non-polar-polymer the non-polar-polymer may be selected from the group of polyalkylene polymers, polyalkylene copolymers, polyakylene block copolymers. In embodiments, the non-polar-polymer may be selected from polymeric aliphatic or aromatic hydrocarbons, for example, polyalkylene polymers, polyalkylene co- and terpolymer with random or block-structure; and as a further example, from polyethylen (PE), polypropylene (PP), polybutene (PB), polystyrene, polyisobutylene, polybutadiene, polyisoprene. In an embodiment, the non-polar-polymer may have a wt % of heteroatoms below 5 wt % with respect to the mass of the non-polar-polymer. In an embodiment, the non-polar polymer may have a molecular weight Mw≥1000 g/mol, for example, Mw≥1200 g/mol, as a further example, Mw≥1500 g/mol.

### Contaminant

The decontamination process allows to decontaminate the plastic article from various types of contaminants, wherein the contaminant is an organic molecule having a molecular weight Mw≤800 g/mol.

With regard to this and according to an embodiment of the invention, the contaminant is embedded in the plastic article and/or molecularly solved in the plastic article and/or the contaminant is not covalently bound to a polymer of the plastic article. In other words, in embodiments, the contaminant is not covalently bound to the polar polymer or to the non-polar polymer of the plastic article.

In an embodiment, the contaminant may be a non-intentionally added substance and present in the plastic article in a range of 0,00001 wt % to 10 wt % based on the weight of the plastic article. This amount corresponds to a concentration of 0.1 ppm to 100.000 ppm. The source of the non-intentionally added substance (NIAS) may be intrinsic due to impurities in the starting materials of the plastic article, may be accumulated in the plastic article during product life or after repeated recycling, may be derived from previous use or misuse of the plastic article or may be a cross contamination. In embodiments, the NIAS may be, for example, a small organic molecule having a molecular weight in the range of Mw≤800 g/mol, as a further example, Mw≤500 g/mol, and as an even further example, Mw≤300 g/mol. Typical NIAS in plastics are formaldehyde, acetaldehyde, propanal, butanal, nonanal, glyoxal, methylglyoxal, acetone, phthalates, PET dimer and trimers, diethylene glycol dibenzoate, chlorohydrins, 2,4-Di-tert-butylphenol, 2,6-Di-tert-butyl-p-benzochinon, N-dodecanoyl-L-tyrosine, 1,4,7-trioxacyclotridecane-8-13-dione, N,N′-Di-2-naphthyl-1,4-phenylenediamine, 2,2′-Thiobis(6-tert-butyl-p-cresol), 4,4′-Thiobis(6-tert-butyl-m-cresol), 2-N-(2,2,6,6-tetramethylpiperidin-4-yl)-2-N-[6-[(2,2,6,6-tetramethylpiperidin-4-yl)amino]hexyl]-4-N-(2,4,4-trimethylpentan-2-yl)-1,3,5-triazine-2,4-diamine (chimasorb 944 light stablizer), 2,6-ditertbutyl-4-methoxyphenol, 3,5-ditertbutyl-4-hydroxybenzoic acid, triphenyl phosphate, tri-o-tolyl phosphate, diphenyl phosphate, 3-(3,5-di-tert-butyl-4-hydroxybenzyl) propionic acid, Nonylphenol, m-phenyolenediamine, 2,6-toluenediamine, 2,4-toluenediamine, 4,4-diaminodiphenylether, 4,4-methylenedianiline, 2-naphtylamine, and/or 4-aminobiphenyl.

In an embodiment, the contaminant may be a coloring agent and present in the plastic article in a range of 0,0001 wt % to 10 wt % based on the weight of the plastic article. This amount corresponds to a concentration of 1 ppm to 100.000 ppm. In an embodiment, the coloring agent is not covalently bond to the plastic article, and as a further example, is not covalently bound to the non-polar polymer or the polar polymer. Therefore, in embodiments, the coloring agent is not a reactive dye. In case the contaminant is a coloring agent, the method of decontaminating the plastic article can also be used for decoloring the plastic article.

In an embodiment, the organic molecule used as coloring agent may be a molecule that absorbs electromagnetic radiation in the visible spectrum, thus the coloring agent gives the plastic article a color that is visibly perceivable by humans. In an embodiment, the coloring agent comprises and/or is an organic molecule, for example, an organic molecule having an aromatic and/or heterocyclic aromatic structure, i.e., an organic aromatic dye and/or the lake pigment of an organic aromatic dye.

With regard to the coloring agent, different types of dyes and/or lake pigments can be used: The coloring agent may be a disperse dye, a solvent dye and/or an acid dye and/or or an acid dye converted into a pigment or a so-called lake pigment, according to the name or designation according to the Color Index. Dyes are predominantly molecularly soluble in the plastic material, in particular in the polar polymer and/or the polar compound, used to produce the plastic article and produce a homogenous either colored-opaque or colored-translucent or -transparent coloration of the plastic article. In an embodiment, the coloring agent is selected from the group comprising phthalocyanine, polymethine, anthraquinone, indanthrone, monoazo, diazo, methine, quinophthalone, perinone, naphthalidimide, indigo, quinoline and thioindigo dyes. In an embodiment, the coloring agent is selected from the group comprising the following chemical formulas A1 to A65 according to table 1:

TABLE 1

| | |
|---|---|
| Chemical formula A1 | 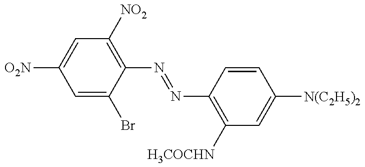 |
| Chemical formula A2 | 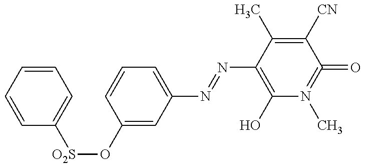 |
| Chemical formula A3 | 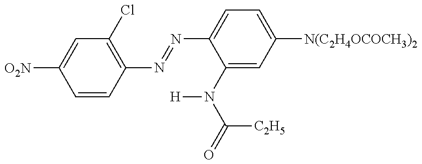 |
| Chemical formula A4 | 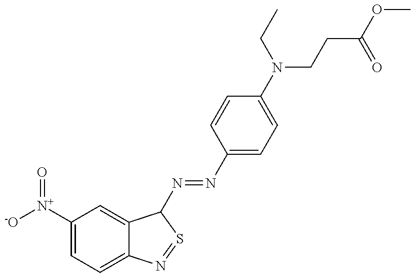 |
| Chemical formula A5: Disperse Blue 56/Bemacron Blau E-FBL | 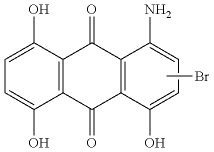 |
| Chemical formula A6 Disperse Red 60 | 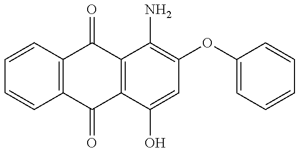 [SMILES: Nc1c(Oc2ccccc2)cc(O)c2c1C(=O)c1ccccc1C2=O] |
| Chemical formula A7 | 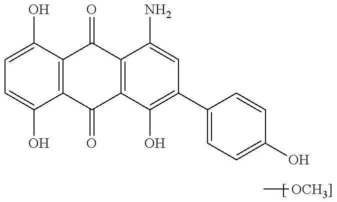 |
| Chemical formula A8 | 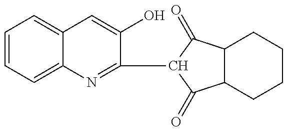 [SMILES: O=C1C(c2nc3ccccc3cc2O)C(=O)C2CCCCC12] |
| Chemical formula A9 | 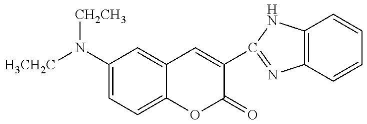 |
| Chemical formula A10 | 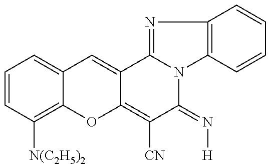 |
| Chemical formula A11: Acid Red 266 | 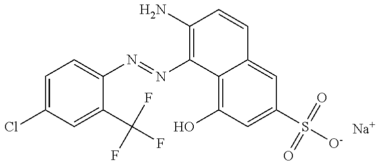 [SMILES: Nc1ccc2cc(S(=O)(=O)[O-])cc(O)c2c1/N=N/c1ccc(Cl)cc1C(F)(F)F ; [Na+]] |
| Chemical formula A12: Acid Blue 62 | 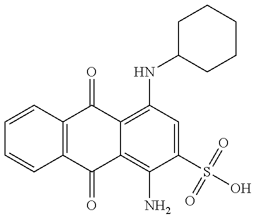 [SMILES: Nc1c(S(=O)(=O)O)cc(NC2CCCCC2)c2c1C(=O)c1ccccc1C2=O] |
| Chemical formula A13: Acid Yewllow 246 | 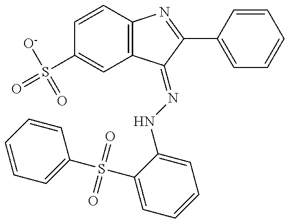 [SMILES: O=S(=O)([O-])c1ccc2c(c1)/C(=N\Nc1ccccc1S(=O)(=O)c1ccccc1)C(c1ccccc1)=N2] |
| Chemical formula A14 | 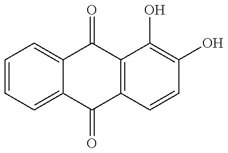 [SMILES: O=C1c2ccccc2C(=O)c2c1ccc(O)c2O] |
| Chemical formula A 15 Solvent Blue 104 | 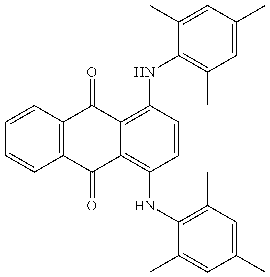 [SMILES: Cc1cc(C)c(Nc2ccc(Nc3c(C)cc(C)cc3C)c3c2C(=O)c2ccccc2C3=O)c(C)c1] |
| Chemical formula A 16 | 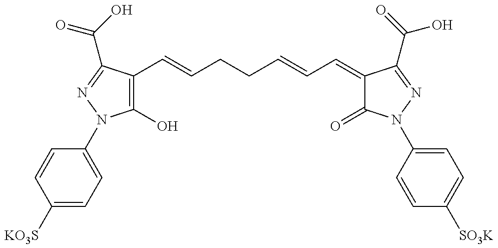 |
| Chemical formula A 17 | 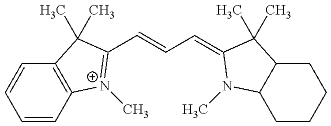 [SMILES: CN1/C(=C\C=C\C2=[N+](C)c3ccccc3C2(C)C)C(C)(C)C2CCCCC21] |
| Chemical formula A18: Disperse Red 278 | 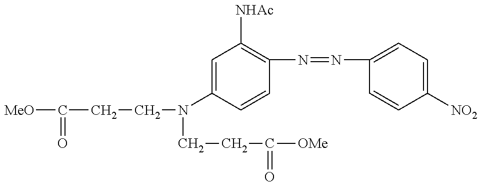 [SMILES: COC(=O)CCN(CCC(=O)OC)c1ccc(N=Nc2ccc([N+](=O)[O-])cc2)c(NC(C)=O)c1] |
| Chemical formula A19: Disperse Brown 19 | 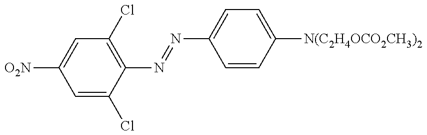 |
| Chemical formula A20: Disperse Orange 30 | 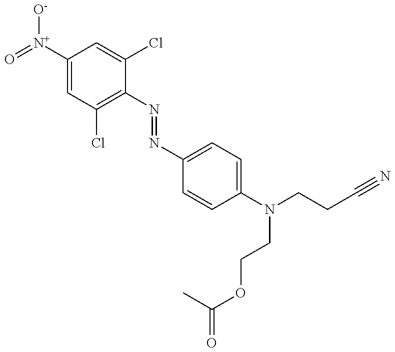 [SMILES: CC(=O)OCCN(CCC#N)c1ccc(/N=N/c2c(Cl)cc([N+](=O)[O-])cc2Cl)cc1] |
| Chemical formula A21: Bemacron Blau HP-LTD | 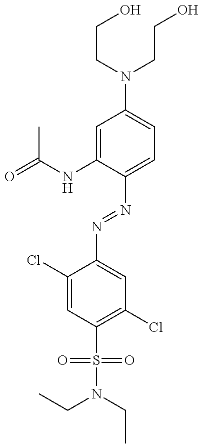 [SMILES: CCN(CC)S(=O)(=O)c1cc(Cl)c(/N=N/c2ccc(N(CCO)CCO)cc2NC(C)=O)cc1Cl] |
| Chemical formula A22: Bemacron Rot HP-LTD 01 | 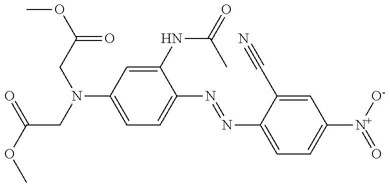 [SMILES: COC(=O)CN(CC(=O)OC)c1ccc(/N=N/c2ccc([N+](=O)[O-])cc2C#N)c(NC(C)=O)c1] |
| Chemical formula A23: Bemacron Gelb HT-LTD01 | 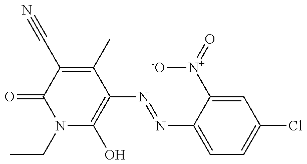 |
| Chemical formula A24 | 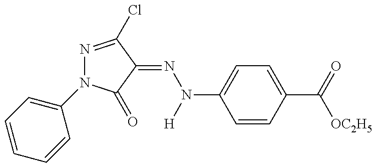 [SMILES: CCOC(=O)c1ccc(N/N=C2\C(=O)N(c3ccccc3)N=C2Cl)cc1] |
| Chemical formula A25: X = {alkyl, aryl, phenyl} Y = {alkyl} | 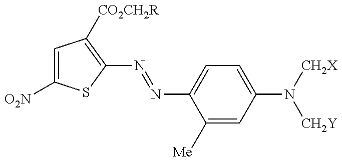 |
| Chemical formula A26 | 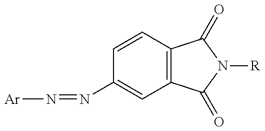 |
| Chemical formula A27 R1 to R5 = {alkyl, aryl} | 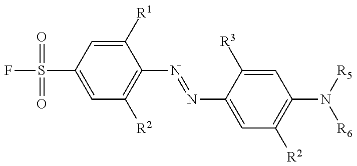 |
| Chemical formula A28 X = SO₂F R = {aryl, alkyl} | 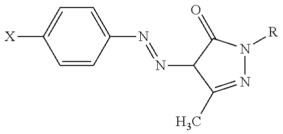 |
| Chemical formula A29 | 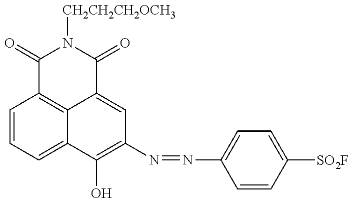 |
| Chemical formula A30 | 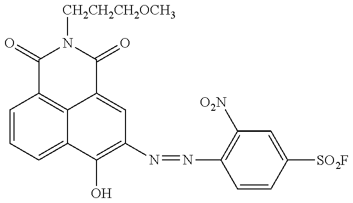 |
| Chemical formula A31 | 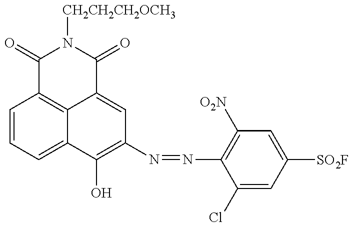 |
| Chemical formula A32: Disperse Green 9 | 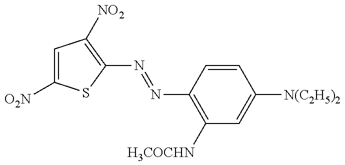 |
| Chemical formula A33 X = {COCOCH₃, CO₂CH₂} Y = {H, NHAc} | 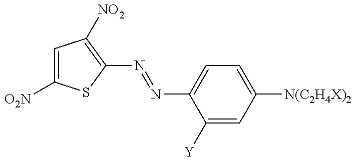 |
| Chemical formula A34 X, Y = {alkyl, aryl, phenyl, C₂H₄Ph} R = {H, Alkyl, CH₂OEt} | 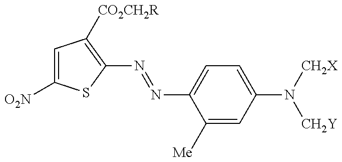 |
| Chemical formula A35 X = {COCOCH₃, CO₂CH₂} | 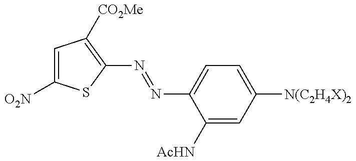 |
| Chemical formula A36 X = N; Y = H; Z = NO₂; or X = C—NO₂, Y = H, Z = NO₂ | 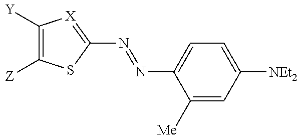 |
| Chemical formula A37 | 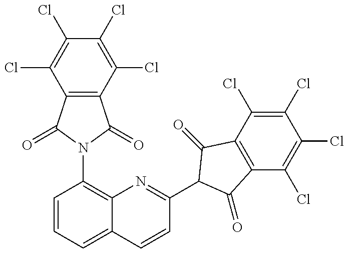 [SMILES: O=C1c2c(Cl)c(Cl)c(Cl)c(Cl)c2C(=O)C1c1ccc2cccc(N3C(=O)c4c(Cl)c(Cl)c(Cl)c(Cl)c4C3=O)c2n1] |
| Chemical formula A38: Allura Red A38 L: Lake Allura Red: Precipitated as Al-salt | 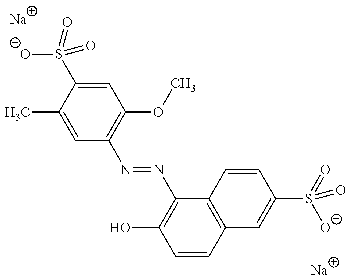 [SMILES: [Na+] ; COc1cc(S(=O)(=O)[O-])c(C)cc1/N=N/c1c(O)ccc2cc(S(=O)(=O)[O-])ccc12 ; [Na+]] |
| Chemical formula A39: Tartrazine A39 L: Lake Tartrazine: Precipitated as Al-salt | 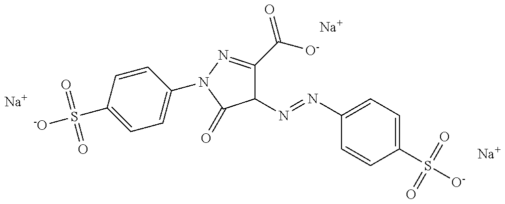 |
| Chemical formula A40: Sunset Yellow A40 L: Lake Sunset Yellow: Precipitated as Al-salt | 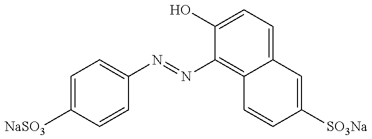 |
| Chemical formula A41: Brilliant Blue FCF A41 L: Lake Brilliant Blue FCF: Precipitated as Al-salt | 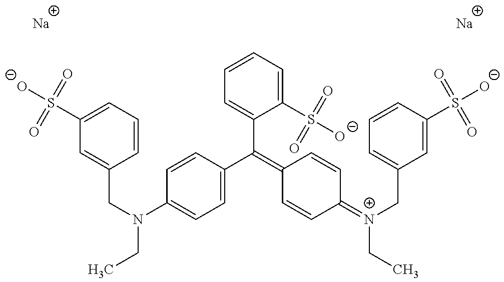 [SMILES: [Na+] ; [Na+] ; CCN(Cc1cccc(S(=O)(=O)[O-])c1)c1ccc(C(=C2C=CC(=[N+](CC)Cc3cccc(S(=O)(=O)[O-])c3)C=C2)c2ccccc2S(=O)(=O)[O-])cc1] |
| Chemical formula A42: Indigo Carmine A42 L: Lake Indigo Carmine: Precipitated as Al-salt | 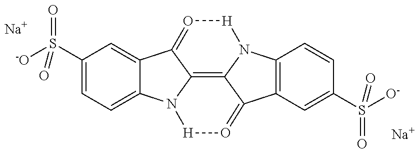 |
| Chemical formula A43: Erythrosine A43 L: Lake Erythrosine: Precipitated as Al-salt | 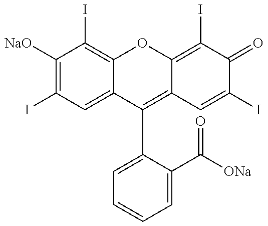 |
| Chemical formula A44: Amaranth A44 L: Lake Amaranth: Precipitated as Al-salt | 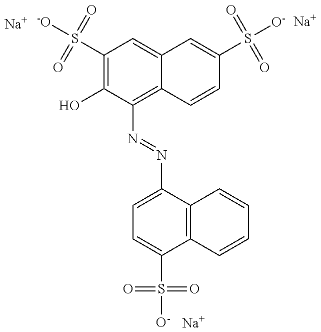 |
| Chemical formula A45: Carmoisine A45 L: Lake Carmoisine: Precipitated as Al-salt | 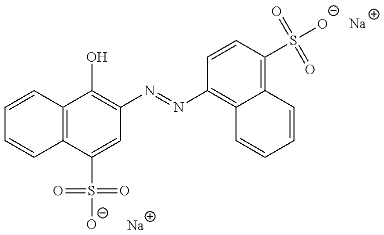 [SMILES: O=S(=O)([O-])c1ccc(/N=N/c2cc(S(=O)(=O)[O-])c3ccccc3c2O)c2ccccc12 ; [Na+] ; [Na+]] |
| Chemical formula A46: Ponceau 4R A46 L: Lake Ponceau 4R: Precipitated as Al-salt | 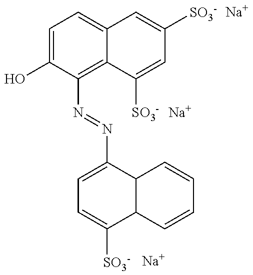 |
| Chemical formula A47: Quinoline Yellow A47 L: Lake Quinoline Yellow: Precipitated as Al-salt | 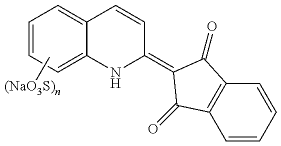 |
| Chemical formula A48: Acid Blue 27 | 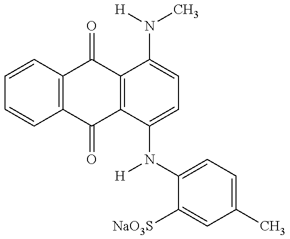 |
| Chemical formula A49: Acid Red 14 | 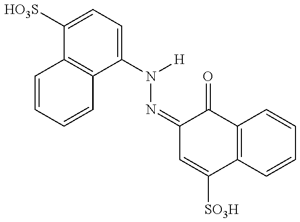 [SMILES: O=C1/C(=N\Nc2ccc(S(=O)(=O)O)c3ccccc23)C=C(S(=O)(=O)O)c2ccccc21] |
| Chemical formula A50: Acid Blue 25 | 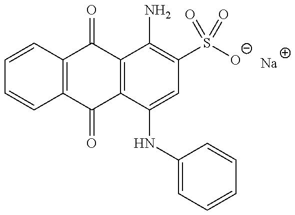 [SMILES: Nc1c(S(=O)(=O)[O-])cc(Nc2ccccc2)c2c1C(=O)c1ccccc1C2=O ; [Na+]] |
| Chemical formula A51: Acid Red 1 | 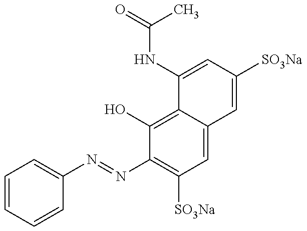 |
| Chemical formula A52: Acid Yellow 11 | 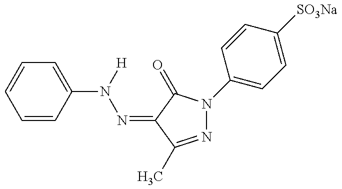 |
| Chemical formula A53: Acid Yellow 23 | 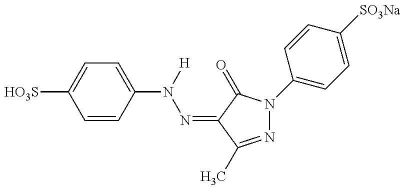 |
| Chemical formula A54: Acid Yellow 36 | 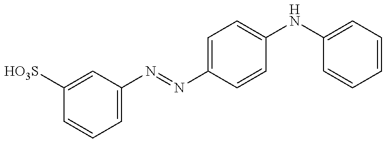 [SMILES: O=S(=O)(O)c1cccc(/N=N/c2ccc(Nc3ccccc3)cc2)c1] |
| Chemical formula A55: Mordant Blue 9 A55 L: Lake Mordant Blue 9: Precipitated as Al-salt | 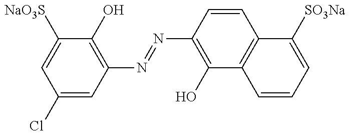 |
| Chemical formula A56 L: Pigment Red 57:1 (Litholrubin BK) Precipitated as Ca-salt: calcium (4Z)-4-[(4-methyl-2- sulfonatophenyl)hydrazono]-3-oxo- 2-naphthalenecarboxylate | 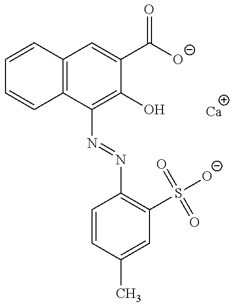 |
| Chemical formula A57: Pigment Yellow 62 A57 L: Pigment Yellow 62 Precipitated as Ca-salt calcium,4-[[4-(2-methylanilino)- 2,4-dioxobutyl]diazeny1]-3- nitrobenzenesulfonate | 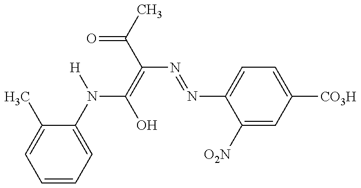 |
| Chemical formula A58: Pigment Red 48:2 A58 L: Pigment Red 48:2 Precipitated as Ca-salt: calcium-4-[(5-chlor-4-methyl-2- sulfonatophenyl)azo]-3-hydroxy-2- naphthoate | 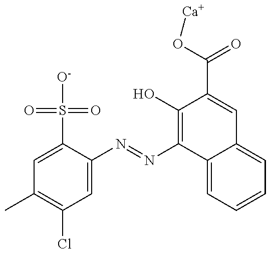 |
| Chemical formula A59: Solvent Red 195 | 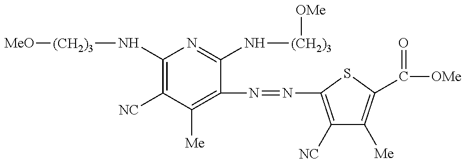 |
| Chemical formula A60: Solvent Yellow 163 | 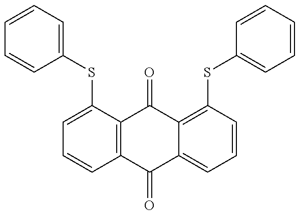 [SMILES: O=C1c2cccc(Sc3ccccc3)c2C(=O)c2c(Sc3ccccc3)cccc21] |
| Chemical formula A61: Pigment Red 177 | 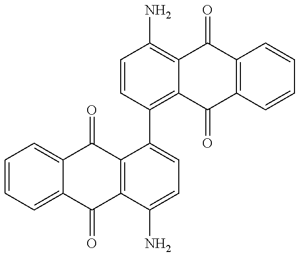 [SMILES: Nc1ccc(-c2ccc(N)c3c2C(=O)c2ccccc2C3=O)c2c1C(=O)c1ccccc1C2=O] |
| Chemical formula A62: Vat Blue 4, Pigment Blue 60, Indanthron | 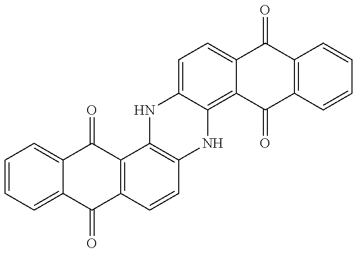 [SMILES: O=c1c2ccccc2c(=O)c2c1ccc1[nH]c3c(ccc4c(=O)c5ccccc5c(=O)c43)[nH]c12] |
| Chemical formula A63: Vat Blue 6 | 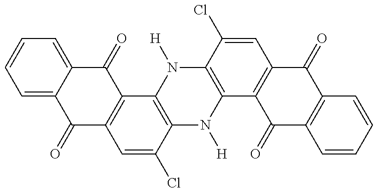 [SMILES: O=c1c2ccccc2c(=O)c2c1cc(Cl)c1[nH]c3c([nH]c12)c(Cl)cc1c(=O)c2ccccc2c(=O)c13] |
| Chemical formula A64: Vat Red 32 | 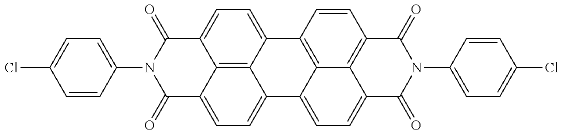 [SMILES: O=C1c2ccc3c4ccc5c6c(ccc(c7ccc(c2c37)C(=O)N1c1ccc(Cl)cc1)c64)C(=O)N(c1ccc(Cl)cc1)C5=O] |

Regarding the chemical formula A7, the methoxy group —[OCH3] may be an alternative for the hydroxyl group —[OH] on the aromatic moiety, that is not part of the anthraquinone ring system.

In an embodiment, the coloring agent is selected from the group comprising the coloring agents known under the trademark BEMACRON S/SE/E from CHT Germany GmbH, or from Dystar Pte Ltd. In an embodiment, the coloring agent is selected from the group comprising BEMACRON Yellow S-6GF, BEMACRON Yellow S-4g, BEMACRON Yellow Brown S-2RFl, BEMACRON Orange S-g, BEMACRON Scarlet S-gFl, BEMACRON Scarlet S-BWFl, BEMACRON Rubine S-2GFL, BEMACRON Violet S-3Rl, BEMACRON Violet S-BlF, BEMACRON Blue S-Bgl, BEMACRON Blue S-BB, BEMACRON Turquoise S-gF, BEMACRON Na-vy S-2gl, BEMACRON Navy 5-31, BEMACRON Black 5-31, BEMACRON Black S-T, BEMACRON Yellow SE-Rdl, BEMACRON Yellow SE-lF, BEMACRON Orange SE-Rdl, BEMACRON Red SE-4g, BEMACRON Pink SE-REl, BEMACRON Red SE-3B, BEMACRON Red SE-Rdl, BEMACRON Blue SE-lF, BEMACRON Blue SE-Rdl, BEMACRON Navy SE-RiX, BEMACRON Black SE-RiX, BEMACRON Black SE-Rd2R, BEMACRON Yellow E-3gl, BEMACRON Red E-FBl, BEMACRON Blue E-FBl, and BEMACRON Black E-R. In an embodiment, the coloring agent is selected from the group comprising BEMACRON Black E-R, BEMACRON Yellow S-6GF, BEMACRON Rubine S-2GFL, BEMACRON Blue RS, BEMACRON Blue E-FBL 150, BEMACRON Red E-FBL, BEMACRON Blue S-BGL, BEMACRON Yellow E-3gl, BEMACRON Lumin. Yellow SEL-8G, and BEMACRON Lumin. Red SEL-G. Furthermore the coloring agent may be selected from the group of acid dyes comprising Bemacid Blau E-TL, Bemacid Rot E-TL or Bemacid Gelb E-TL, Bemacid Blue N-TF, Bemacid Red N-TF, Bemacid Yellow N-TF, Bemacid Leuchtgelb E-B, Bemacid Gelb E-4G, Bemacid Gelb E-T3R, Bemacid Gelb E-5R, Bemacid Leuchtrot E-B, Bemacid Rot E-KRL, Bemacid Rot E-T2B, Bemacid Rot E-3BS, Bemacid Blau E-2R, Bamacid Blau E-T4R, Bemacid Blau E-G, Bemacid Blau E-3GC, Bemacid Gelb N-2G, Bemacid Orange N-BG, Bemacid Rubin N-5B, Bemacid Bordeaux N-BL, Bemacid Blau N-5GL, Bemacid Marine N-5R, Bemacid Schwarz N-TMF, or the group of metal complex dyes Bemaplex BEMAPLEX Gelb M-T, BEMAPLEX Rot M-T and BEMAPLEX Marine M-T.

Furthermore, the coloring agent may be a solvent dye such as Solvent Blue 13, Solvent Blue 35, Solvent Blue 47, Solvent Blue 70, Solvent Blue 97, Solvent Blue 104, Solvent Blue 122, Solvent Red 111, Solvent Red 135, Solvent Red 146, Solvent Red 149, Solvent Red 168, Solvent Red 172, Solvent Red 195, Solvent Red 207 or Solvent Yellow 114, Solvent Yellow 163, Solvent Yellow 167 or Solvent Yellow 197. Furthermore, the coloring agent may be selected from the group comprising polymethine dyes. In an embodiment, the polymethine dyes from the companies BUFA GmbH & Co. KG, BUFA Chemikalien GmbH & Co. KG, BUFA Composite Systems GmbH & Co. KG, and/or BUFA Reinigunssysteme GmbH & Co. KG may be used.

The coloring agent may be a ready-to-use dye, i.e., a dye comprising a dispersing agent or another additive, for example to ensure sufficient solubility in a coloring bath or incorporated in the carrier of a color master batch. Alternatively, it may be a dye not comprising a dispersing agent or any additive. Various acid dyes can be converted to the water-insoluble so-called lake pigments, which are usually aluminium and/or calcium salts of the corresponding acid dyes. These lake pigments usually exhibit sufficient color stability against external influences, such that the tendency for migration is strongly reduced. Furthermore, the lake pigments can be transformed back into water-soluble components, which makes a decontamination of the plastic article possible.

### Form of Plastic Article

In principle the plastic article can have any form. It is also possible to decontaminate entire plastic articles, without destroying the plastic article or altering its form. In this regard and according to an embodiment of the invention the plastic article that is exposed to the decontamination bath is an intact plastic article, a plastic granulate and/or plastic powder. A plastic granulate and/or powder compared to an intact plastic article may be decontaminated faster, as the surface to volume ratio may be higher for the granulate and/or powder than for the intact plastic article.

According to the above, embodiments of the method may comprise the step of shredding the plastic article to a granulate and/or powder and wherein the step of exposing the plastic article to the decontamination bath comprises exposing the shredded plastic article to the decontamination bath.

In an embodiment, the granulate and/or powder comprises a mean particle size of 0.1 mm to 50 mm. In embodiments, the mean particle size of the plastic granulate and/or powder may be determined with sieving methods and sieve series selected according to the standard ISO 3301, DIN 66165 and/or by photoanalysis.

In an embodiment, the plastic article is selected from the group comprising a sheet, a foil, a container, a part, a tube, a profile, a rigid packaging such as bottles, jars, caps and closures, color coded packaging and containers of all types, including ones for industrial components, computer face-plates, keyboards, bezels and cellular phones, residential and commercial lighting fixtures and components therefor, such as sheets, used in building and in construction, tableware, including plates, cups and eating utensils, small appliances and their components, optical and sun-wear lenses, and/or wherein the plastic article is a granulate and/or powder from plastic recycling and/or wherein the plastic article is not a textile.

### Decontamination Process Parameters

According to an embodiment of the invention for the step of exposing the plastic article to the decontamination bath a weight ratio of the contaminant in the plastic article to the resoiling inhibitor is from 1:0.001 to 1:100.000.000 (contaminant:resoiling inhibitor). In an embodiment, the weight ratio of the contaminant in the plastic article to the resoiling inhibitor is from 1:0.1 to 1:10.000, and for example, from 1:1 to 1:100 (contaminant:resoiling inhibitor).

According to an embodiment of a weight ratio of the plastic article to the decontamination bath is from 1:1 to 1:100 (plastic article:decontamination bath), for example, from 1:2 to 1:20, and as a further example, from 1:3 to 1:6 (plastic article:decontamination bath).

It has been found that these ratios of resoiling inhibitor to contaminant and plastic article to decontamination bath are advantageous in terms of decontamination efficiency and waste management.

### Time and Temperature

According to an embodiment of the invention the plastic article is exposed to the decontamination bath for ≥1 minute to ≤240 minutes, for example, ≥10 minute to ≤180 minutes, as a further example, for ≥20 minutes to about ≤120 minutes.

In embodiments it may be desired that the decontamination bath has a temperature adjusted according to specific properties of the plastic article. In an embodiment, the decontamination bath may have a temperature selected ≥a glass-transition temperature T_{g} and/or below a decomposition temperature of the plastic article. This may have the advantages that the decontamination of the plastic article is speeded up.

The glass transition temperature T_{g} may be the gradual and reversible transition in amorphous regions of the plastic article from a hard and relatively brittle state into a viscous or rubbery state as the temperature is increased. The glass transition temperature T_{g} of the plastic article may be determined by differential scanning calorimetry (DSC), which is a thermoanalytical technique in which the difference in the amount of heat required to increase the temperature of a sample and reference is measured as a function of temperature.

In embodiments, the glass transition temperature T_{g} may be determined according to the following standards: DIN 51007 (Thermal Analysis—Differential Thermal Analysis and Differential Scanning Calorimetry—General Principles), ASTM E 474, ASTM D 3418, DIN EN ISO 11357-1 (Plastics—Differential Scanning Thermal Analysis Part 1: General principles. (2008)), ISO 11357-2 (Plastics—Differential Scanning Calorimetry Part 2: Determination of the glass transition temperature. (1999)), ISO/DIS 11357-3 (Plastics—Differential Scanning Calorimetry Part 3: Determination of the melting and crystallization temperature and the melting and crystallization enthalpy. (2009)), ISO 11357-4 (Plastics—Differential Scanning Thermal Analysis (DSC) Part 4: Determination of specific heat capacity. (2005)).

In embodiments, the glass transition temperature T_{g} may be determined using a Mettler Toledo DSC 3+ differential calorimeter, a sample amount of 10+/−1 mg, nitrogen as purge gas, and the following settings: 1. Heating: −40° C. to 280° C. with 20° C./min, Hold: 3 minutes at 200° C., Cooling: 280° C. to −40° C. at 10° C./min, Hold: 5 minutes at −20° C., 2. Heating: −40° C. to 300° C. at 20° C./min.

The melting temperature Tₘ and/or decomposition temperature of the plastic article may be determined according to the same standards and procedures as used for determining the glass transition temperature T_{g} of the plastic article. Not all polymers can be molten, e.g., elastomers unlike thermoplastics cannot be molten. Heating only leads to decomposition, where the chemical structure of the polymer decomposes. In an embodiment, the decomposition temperature refers to the temperature were thermal degradation takes place, i.e., where damaging chemical changes take place, without the simultaneous involvement of other compounds such as oxygen. The decomposition temperature of the plastic article may also be determined by thermogravimetric analysis (TGA).

In an embodiment, the temperature of the decontamination bath and exposure time may be used to control the decontamination process with regard to the type of decontaminant. In embodiments, decontaminants with higher molecular weight may be decontaminated at higher temperature. In order to decontaminate a plastic article comprising a coloring agent and a further contaminant, wherein the further contaminant is not a coloring agent and has a lower molecular weight than the coloring agent, without decoloring the plastic article a method is provided wherein the step of exposing the plastic article to the decontamination bath comprises exposing the plastic article to the decontamination bath at a temperature ≥60° C. to ≤100° C., for example, temperature ≥60° C. to ≤95° C. for ≥1 minute to ≤120 minutes, as a further example, ≥1 minute to ≤60 minutes.

According to an embodiment of the invention a method is provided wherein the step of exposing the plastic article to the decontamination bath comprises exposing the plastic article to the decontamination bath at a temperature ≥60° C. to ≤100° C., for ≥1 min to ≤120 min, and for example, for ≥1 min to ≤60 min, and subsequently exposing the plastic article to the decontamination bath at a temperature ≥80° C. to ≤130° C., for ≥1 minute to ≤120 min, for example, for ≥1 min to ≤60 min. Alternatively the step of exposing the plastic article to the decontamination bath comprises exposing the plastic article to the decontamination bath at a temperature ≥80° C. to ≤130° C., for example, ≥90° C. to ≤130° C., for ≥1 min to ≤120 min. In embodiments, this may be particularly desired for plastic articles comprising a contaminant not being a coloring agent and in addition a coloring agent, and that shall be decontaminated and decolored in one process. In embodiments, the method where the temperature of the decontamination bath is in a first time period lower and afterwards in a second time period higher may be advantageous in terms of energy consumption.

### Drying

In an embodiment, the method comprises the step of drying the decontaminated plastic article in air. In an embodiment, after exposing the plastic article to the decontamination bath, the plastic article is extracted from the decontamination bath and dried, for example, at elevated temperatures. In an embodiment, the plastic article is dried at 60° C. to 80° C. for a duration of 1 hours to 8 hours.

### DETAILED DESCRIPTION OF THE EXAMPLES

Embodiments of the invention will be described in the following with reference to the exemplary examples and to comparative examples (decontamination bath A′).

For all examples sample plastic articles in the form of a plate have been produced by mixing a plastic material with a masterbatch in an extruder and by injection molding the plastic article in the form of the plate having W×H×T=30×50×1 mm³. Table 2 specifies the plastic material, the compositions of the masterbatch, the mixing ratio of the masterbatch with the plastic material and the resulting concentration of the contaminant the plastic articles. The molecular structure of the contaminant is given in table 3.

TABLE 2
Plastic material, compositions of the masterbatch,
mixing ratio of the masterbatch
with the plastic material and resulting
concentration of decontaminant the plastic article

| | | | weight | |
|---|---|---|---|---|
| | | | ratio | Concentration |
| | | | Plastic | contaminant in |
| | | | material: | Plastic article |
| | Plastic material | Masterbatch composition | Masterbatch | [%] |
| 1 | PE (Lyondell | mixture of plastic material, ethyl- | 96:4 | 0.1% |
| | Basell | methacrylat-copolymer (Lotryl | | |
| | Hostalen ACP | 18MA02), acetyltributylcitrate | | |
| | 5831 D) | (ATBC) and as contaminant dye | | |
| | | A15 in a weight ratio of | | |
| | | 35:60:2.5:2.5. | | |
| 2 | PE (Lyondell | mixture of plastic material, ethyl- | 96:4 | 0.1% |
| | Basell | methacrylat-copolymer (Lotryl | | |
| | Hostalen ACP | 18MA02), acetyltributylcitrate | | |
| | 5831 D) | (ATBC) and as contaminant dye | | |
| | | A59 in a weight ratio of | | |
| | | 35:60:2.5:2.5. | | |
| 3 | PE (Lyondell | mixture of plastic | 96:4 | 0.1% |
| | Basell | material, ethyl- | | |
| | Hostalen ACP | methacrylat-copolymer (Lotryl | | |
| | 5831 D) | 18MA02), acetyltributylcitrate | | |
| | | (ATBC) and as contaminant dye | | |
| | | A60 in a weight ratio of | | |
| | | 35:60:2.5:2.5. | | |
| 4 | PE (Lyondell | mixture of plastic material, ethyl- | 96:4 | 0.1% |
| | Basell | methacrylat-copolymer (Lotryl | | |
| | Hostalen ACP | 18MA02), polyvinylalcohol | | |
| | 5831 D) | (Mowiflex C 30), | | |
| | | acetyltributylcitrate (ATBC) and | | |
| | | as contaminant dye A61 in a | | |
| | | weight ratio of 25:45:25:2.5:2.5 | | |
| 5 | PE (Lyondell | mixture of plastic material, ethyl- | 96:4 | 0.1% |
| | Basell | methacrylat-copolymer (Lotryl | | |
| | Hostalen ACP | 18MA02), polyvinylalcohol | | |
| | 5831 D) | (Mowiflex C 30), | | |
| | | acetyltributylcitrate (ATBC) and | | |
| | | as contaminant dye A62 in a | | |
| | | weight ratio of 25:45:25:2.5:2.5 | | |
| 6 | PE (Lyondell | mixture of plastic material, ethyl- | 99:1 | 10 ppm |
| | Basell | methacrylat-copolymer (Lotryl | | |
| | Hostalen ACP | 18MA02), acetyltributylcitrate | | |
| | 5831 D) | (ATBC) and as contaminant Con | | |
| | | 1 in a weight ratio of | | |
| | | 37.4:60:2.5:0.1 | | |
| 7 | PE (Lyondell | mixture of the plastic material, | 99:1 | 10 ppm |
| | Basell | ethyl-methacrylat-copolymer | | |
| | Hostalen ACP | (Lotryl 18MA02), | | |
| | 5831 D) | acetyltributylcitrate (ATBC) and | | |
| | | as contaminant Con 2 in a weight | | |
| | | ratio of 37.4:60:2.5:0.1 | | |
| 8 | PE (Lyondell | mixture of plastic material, ethyl- | 96:4 | 0.1% for A15 |
| | Basell | methacrylat-copolymer (Lotryl | | and 10 ppm for |
| | Hostalen ACP | 18MA02), acetyltributylcitrate | | Con 2 |
| | 5831 D) | (ATBC) and as contaminant dye | | |
| | | A15 in a weight ratio of | | |
| | | 34.975:60:2.5:2.5:0.025 | | |

TABLE 3
Name and chemical structure of contaminant

| contaminant | Structure |
|---|---|
| A 15: Solvent Blue 104 | 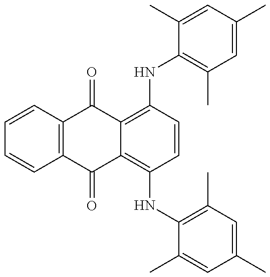 [SMILES: Cc1cc(C)c(Nc2ccc(Nc3c(C)cc(C)cc3C)c3c2C(=O)c2ccccc2C3=O)c(C)c1] |
| A59 Solvent Red 195 | 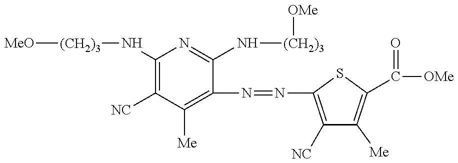 |
| A60: Solvent Yellow 163 | 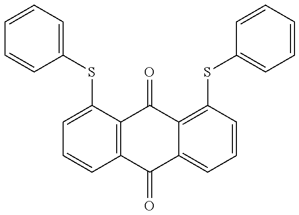 [SMILES: O=C1c2cccc(Sc3ccccc3)c2C(=O)c2c(Sc3ccccc3)cccc21] |
| A 61: Pigment Red 177 | 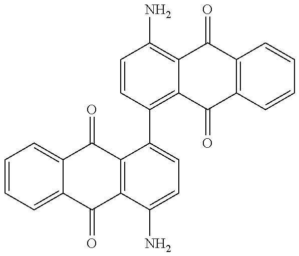 [SMILES: Nc1ccc(-c2ccc(N)c3c2C(=O)c2ccccc2C3=O)c2c1C(=O)c1ccccc1C2=O] |
| A62: Vat Blue 4, Pigment Blue 60, Indanthron | 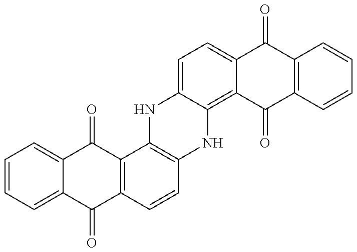 [SMILES: O=c1c2ccccc2c(=O)c2c1ccc1[nH]c3c(ccc4c(=O)c5ccccc5c(=O)c43)[nH]c12] |
| Con 1: Geraniol | 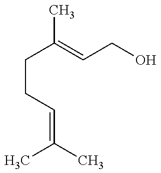 |
| Con 2: α-Hexylcinnamaldehyde | 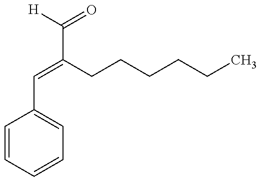 [SMILES: CCCCCC/C(C=O)=C\c1ccccc1] |

With regard to samples 1 to 5 and 8, where the contaminant is a coloring agent, the color of the plastic article has been determined by a photospectrometer after production of the plastic platelets (see table 4).

TABLE 4
Color value of platelets comprising
a coloring agent as contaminant

| sample | LAB | RGB |
|---|---|---|
| 1 (A15) | 40/34/-75 | 0/83/220 |
| 2 (A59) | 41/66/28 | 192/4/54 |
| 3 (A60) | 95/-20/93 | 252/248/0 |
| 4 (A61) | 55/72/63 | 250/51/19 |
| 5 (A62) | 3/80/-108 | 0/0/170 |
| 8 (A15) | 42/33/-73 | 33/88/222 |

Colors can be described in the RGB or in the Lab color space. In the examples the coloration of the samples is determined in the Lab color space and measured with a Spectrometer Konika-Minolta CM-3600A—according to the guideline of the INSTRUCTION MANUAL CM-3600A (©2011-2013 KONICA MINOLTA, INC.). The Lab color can be converted into the RGB color.

### The Principle of the RGB Color Space

This principle is based on the three-color theory. The RGB color space works on the principle of the additive color space. This means that it reproduces the entire color range by mixing the basic colors red, green and blue. The RGB color space can be found in all self-illuminating systems, such as monitors or television screens. All possible colors are defined by their red, green and blue components and mapped accordingly by the overlay of colored light.

### The Principle of the Lab Color Space

Unlike the RGB color space, the Lab color space is based on counter-color theory. This is based on the assumption that three separate chemical processes take place in the human retina, which always contain two opposite colors, the two opposite colors striving for balance with one another. An example pair would be the combination of blue and yellow. Lab is used, for example, for photo editing software. While the RGB color space is device-dependent, it is not the Lab color space. RGB includes—regardless of the device—all potentially possible colors, which above all enables the conversion of color definitions from one device to the other.

### Convert RGB to Lab

It is important for the conversion that Lab coordinates separate brightness information L from the rest of the color information. RGB images do not have such a separation—a change in brightness therefore changes the entire color information.
Convert sRGB to Lab: http://colormine.org/convert/rgb-to-lab
Conversion Lab to sRGB: http://colormine.org/convert/lab-to-rgb

### Decontamination

The decontamination of the plastic articles was performed according to the following procedures. The platelet was shredded to a granulate having a mean particles size of approximately 2 mm. Afterwards the granulate was exposed to a decontamination bath. After having been exposed to the decontamination bath the granulates are filtered off with a coarse sieve and thoroughly rinsed firstly with water of 80° C. containing 3 g/L polyvinylpyrrolidone in water (50 wt %), secondly with cold water and dried at 80° C. for 6 h on air. The granulates of sample 4 and 5 are firstly rinsed with water of 80° C. containing 3 g/L polyvinylpyrrolidone in water (50 wt %), secondly with water of 80° C. containing 3 g/L of a 1:1 mixture of a disodium metasilicate pentahydrate and phosphates in water (50 wt %) and at least with cold water and dried at 80° C. for 6 h on air.

The exemplary decontamination baths A to F comprises water, an alkaline agent, a non-polar organic solvent component, an anionic and/or non-ionic surfactant, a resoiling inhibitor and a reducing agent. The comparative decontamination bath A′ does not comprise a resoiling inhibitor. The compositions are given in table 5. The concentrations in table 5 are given with respect to the volume of the decontamination bath.

TABLE 5
Compositions of exemplary decontamination baths
A to F, and comparative decontamination bath A′

| | Alkaline | non-polar organic | anionic and/or non- | resoiling | Reducing | |
|---|---|---|---|---|---|---|
| | agent | solvent component | ionic surfactant | inhibitor | agent | pH |
| A | 20 g/L | 150 mL/L of | 5 g/L of a mixture of | 3 g/L | 5 g/L | >10, |
| | NaOH | C7 to C9- | Na-alkyl | PVP | hydrosulfite | adjusted |
| | (solid) | aliphatic | benzenesulfonate | (25%) in | (Na₂S₂O₄) | by |
| | | hydrocarbons | (C10-C13) (20%) and | water | | NaOH |
| | | | Isotridecanolethoxylate | | | |
| | | | (20%) in water | | | |
| B | 20 g/L | 150 mL/L of | 5 g/L of a mixture of | 3 g/L | 5 g/L | >10, |
| | NaOH | C9 to C11- | Na-alkyl | PVP | hydrosulfite | adjusted |
| | (solid) | aliphatic | benzenesulfonate | (25%) in | (Na₂S₂O₄) | by |
| | | hydrocarbons | (C10-C13) (20%) and | water | | NaOH |
| | | | Isotridecanolethoxylate | | | |
| | | | (20%) in water | | | |
| C | 20 g/L | 150 mL/L of | 5 g/L of a mixture of | 3 g/L | 5 g/L | >10, |
| | NaOH | C11 to C12- | Na-alkyl | PVP | hydrosulfite | adjusted |
| | (solid) | aliphatic | benzenesulfonate | (25%) in | (Na₂S₂O₄) | by |
| | | hydrocarbons | (C10-C13) (20%) and | water | | NaOH |
| | | | Isotridecanolethoxylate | | | |
| | | | (20%) in water | | | |
| D | 20 g/L | 150 mL/L of | 5 g/L of a mixture of | 3 g/L | 5 g/L | >10, |
| | NaOH | C11 to C14- | Na-alkyl | PVP | hydrosulfite | adjusted |
| | (solid) | aliphatic | benzenesulfonate | (25%) in | (Na₂S₂O₄) | by |
| | | hydrocarbons | (C10-C13) (20%) and | water | | NaOH |
| | | | Isotridecanolethoxylate | | | |
| | | | (20%) in water | | | |
| E | 20 g/L | 150 mL/L | 5 g/L of a mixture of | 3 g/L | 5 g/L | >10, |
| | NaOH | C7 to C8- | Na-alkyl | PVP | hydrosulfite | adjusted |
| | (solid) | isoparaffine | benzenesulfonate | (25%) in | (Na₂S₂O₄) | by |
| | | | (C10-C13) (20%) and | water | | NaOH |
| | | | Isotridecanolethoxylate | | | |
| | | | (20%) in water | | | |
| F | 20 g/L | 35 mL/L | 5 g/L of a mixture of | 3 g/L | 5 g/L | >10, |
| | NaOH | C7 to C9- | Na-alkyl | PVP | hydrosulfite | adjusted |
| | (solid) | aliphatic | benzenesulfonate | (25%) in | (Na₂S₂O₄) | by |
| | | hydrocarbons | (C10-C13) (20%) and | water | | NaOH |
| | | | Isotridecanolethoxylate | | | |
| | | | (20%) in water | | | |
| A′ | 20 g/L | 150 mL/L of | 5 g/L of a mixture of | | 5 g/L | >10, |
| | NaOH | C7 to C9- | Na-alkyl | | hydrosulfite | adjusted |
| | (solid) | aliphatic | benzenesulfonate | | (Na₂S₂O₄) | by |
| | | hydrocarbons | (C10-C13) (20%) and | | | NaOH |
| | | | Isotridecanolethoxylate | | | |
| | | | (20%) in water | | | |

The samples according to examples 1 to 8 have been decontaminated by the exemplary decontamination bath A and the comparative decontamination bath A′. Furthermore, sample 1 has also been decontaminated by the decontamination bath E, samples 2, 3, and 7 have also been decontaminated by the decontamination baths B to D, sample 6 has also been decontaminated by the decontamination bath F. Table 6 gives an overview about the performed decontaminations and indicates the conditions for exposure to the decontamination bath. For the decontamination examples No. 26 and 27 the temperature for the decontamination bath was not constant during decontamination. Instead, for a first duration the temperature of the decontamination bath was set to a first temperature. Subsequently the temperature of the decontamination bath was raised to a second temperature and hold for a second duration.

TABLE 6
Conditions for decontamination examples

| # | Sample | Bath | Temperature | Time | Ratio of granulate to Bath |
|---|---|---|---|---|---|
| 1 | 1 | A | 95° C. | 120 min | 25 g to 250 g |
| 2 | 2 | A | 105° C. | 60 min | 25 g to 250 g |
| 3 | 3 | A | 105° C. | 60 min | 25 g to 250 g |
| 4 | 4 | A | 105° C. | 120 min | 25 g to 250 g |
| 5 | 5 | A | 105° C. | 120 min | 25 g to 250 g |
| 6 | 6 | A | 95° C. | 60 min | 25 g to 250 g |
| 7 | 7 | A | 95° C. | 60 min | 25 g to 250 g |
| 8 | 8 | A | 105° C. | 120 min | 25 g to 250 g |
| 9 | 1 | A′ | 95° C. | 120 min | 25 g to 250 g |
| 10 | 2 | A′ | 105° C. | 60 min | 25 g to 250 g |
| 11 | 3 | A′ | 105° C. | 60 min | 25 g to 250 g |
| 12 | 4 | A′ | 105° C. | 120 min | 25 g to 250 g |
| 13 | 5 | A′ | 105° C. | 120 min | 25 g to 250 g |
| 14 | 6 | A′ | 95° C. | 60 min | 25 g to 250 g |
| 15 | 7 | A′ | 95° C. | 60 min | 25 g to 250 g |
| 16 | 8 | A′ | 105° C. | 120 min | 25 g to 250 g |
| 17 | 2 | B | 105° C. | 120 min | 25 g to 250 g |
| 18 | 3 | B | 105° C. | 120 min | 25 g to 250 g |
| 19 | 7 | B | 105° C. | 120 min | 25 g to 250 g |
| 20 | 2 | C | 105° C. | 120 min | 25 g to 250 g |
| 21 | 3 | C | 105° C. | 120 min | 25 g to 250 g |
| 22 | 7 | C | 105° C. | 120 min | 25 g to 250 g |
| 23 | 2 | D | 105° C. | 120 min | 25 g to 250 g |
| 24 | 3 | D | 105° C. | 120 min | 25 g to 250 g |
| 25 | 7 | D | 105° C. | 120 min | 25 g to 250 g |
| 26 | 8 | A | 60° C. | 60 min | 25 g to 250 g |
| | | | 105° C. | 60 min | |
| 27 | 8 | A | 80° C. | 60 min | 25 g to 250 g |
| | | | 105° C. | 60 min | |
| 28 | 1 | E | 105° C. | 120 min | 25 g to 250 g |
| 29 | 6 | F | 95° C. | 60 min | 25 g to 250 g |

For the samples comprising a coloring agent as contaminant the decontamination effect can be determined by measuring the color values and the remaining color strength after decontamination. For this the color value and color strength of the granulate has been determined after being exposed to the decontamination bath, however before the drying of the granulate. Furthermore, the color value was also determined after the decontaminated granulates have been dried and molded again by injection molding into new platelets (see table 7).

The remaining color strength is determined the spectrophotometer. The remaining color strength is the color strength K/S of the plastic article before decontamination minus the loss of color strength K/S by the decontamination process in % with color strength K/S according to Kubelca-Munk. Color strength according to Kubelca-Munk can be determined by the spectrophotometer Konica-Minolta 3600A at maximum absorbance. The remaining color strength is calculated as follows:

$$remaining color strength = 1 - \frac{( color strength before - color strength after )}{color strength before} in \%$$

According to Kubelka-Munk, there is a linear relationship between the color strength and the color content or concentration in a plastic. Therefore, a remaining color strength in percent after decontamination corresponds to the remaining coloring agent content after decontamination.

TABLE 7
Color values after decontamination for samples
comprising a coloring agent as contaminant

| | | | Color values and remaining color | | | Color values and remaining color | | |
|---|---|---|---|---|---|---|---|---|
| | | | strength after decontamination | | | strength after decontamination, after | | |
| | | | and before drying | | | drying and after molding new platelet | | |
| # | Sample | Bath | LAB | RGB | % | LAB | RGB | % |
| 1 | 1 | A | 98/−3/1 | 244/251/247 | <5 | 97/−6/3 | 236/248/239 | <5 |
| 2 | 2 | A | 91/8/−2 | 243/224/233 | <5 | 93/11/−4 | 255/239/243 | <5 |
| 3 | 3 | A | 99/−4/4 | 247/254/244 | <5 | 98/−4/19 | 255/250/212 | <5 |
| 4 | 4 | A | 83/21/12 | 253/192/185 | <10 | 83/21/14 | 253/191/181 | <10 |
| 5 | 5 | A | 79/13/−25 | 197/190/242 | <10 | 80/13/−28 | 196/194/252 | <10 |
| 8 | 8 | A | 95/−8/2 | 226/246/236 | <5 | 92/−4/1 | 225/234/230 | <5 |
| 9 | 1 | A′ | 95/−7/234 | 230/220/221 | <5 | 89/−9/1 | 204/220/221 | <5 |
| 10 | 2 | A′ | 95/8/0 | 255/235/240 | <5 | 94/5/5 | 251/233/228 | <5 |
| 11 | 3 | A′ | 96/−4/23 | 225/245/200 | <5 | 94/−19/78 | 246/246/73 | <5 |
| 12 | 4 | A′ | 78/30/17 | 255/170/163 | <10 | 72/41/23 | 255/145/137 | <10 |
| 13 | 5 | A′ | 77/14/−33 | 185/185/251 | <10 | 65/25/−25 | 147/147/250 | <10 |
| 16 | 8 | A′ | 89/−10/0 | 202/229/223 | <5 | 83/−13/5 | 184/214/197 | <5 |
| 17 | 2 | B | 92/12/−1 | 255/225/234 | <5 | 92/10/−1 | 250/226/235 | <5 |
| 18 | 3 | B | 97/−6/27 | 255/248/193 | <5 | 96/−6/24 | 251/245/196 | <5 |
| 20 | 2 | C | 78/31/0 | 78/31/0 | <10 | 77/37/13 | 251/167/166 | <10 |
| 21 | 3 | C | 95/−11/43 | 95/−11/43 | <10 | 94/−10/39 | 246/241/161 | <10 |
| 23 | 2 | D | 73/37/11 | 73/37/11 | <15 | 74/30/17 | 242/160/152 | <15 |
| 24 | 3 | D | 94/−10/42 | 94/−10/42 | <15 | 95/−15/42 | 241/246/158 | <15 |
| 26 | 8 | A | 29/71-98 | 0/86/226 | >50 | 43/29/−72 | 11/93/223 | >50 |
| | | | 69/−3/−48 | 79/174/255 | <30 | 70/−10/−41 | 74/181/246 | <30 |
| 27 | 8 | A | 50/30/−78 | 2/111/255 | >50 | 80/−33/−28 | 4/218/250 | >50 |
| | | | 79/−12/−29 | 129/203/247 | <25 | 81/−20/−22 | 122/214/241 | <25 |
| 28 | 8 | E | 99/−7/4 | 241/255/244 | <5 | 98/−9/5 | 235/255/239 | <5 |

In order to determine the decontamination success for the samples comprising the contaminants Con 1 and Con 2, quantitative determination of the residual contaminant content of Con 1 and Con 2 is performed by GC/MS after decontamination and drying at 80° C. for 6 h at the level of the granulate (see table 9).

Analysis of Contaminants with Headspace Solid-Phase Microextraction and Gas Chromatography and Mass Spectrometry

### Extraction of Contaminants Using Headspace Solid Phase Microextraction

The headspace solid-phase microextraction (HS-SPME) technique was applied to analyze the contaminants from the polymer matrix. A total of 10±0.01 g of each sample was introduced in a glass vial of 100 mL volume sealed with a 20 mm diameter Teflon/Silicone septum. Next, an SPME syringe with a 75 μm Carboxen/Polydimethylsiloxane fiber was injected through the septum and held in the vial headspace while adsorbing the contaminants emitted by the plastic sample. The contaminants extraction was facilitated by heating the sample in a water bath at 60 C for 1 h while the SPME fiber was placed inside.

### 2. Analysis of Contaminants by Gas Chromatography and Mass Spectrometry

The contaminants adsorbed on the fiber were desorbed in the injection port of the gas chromatograph Agilent 7890A (GC), where the compounds were separated using a non-polar HP5 capillary column (30 m length, 0.25 mm diameter, supplied by Agilent Technologies), after which the mass spectrum of each molecule was obtained with the Mass Spectrometer Agilent 5975C (MS). The method set in the GC/MS for the contaminants analysis is described in the table 8:

TABLE 8
Operating conditions in the gas
chromatography mass spectrometry device.

| GC conditions | | |
|---|---|---|
| Split mode | 5:1 | |
| Injector | 280° | C. |
| temperature | | |
| Desorption time | 10 | min |
| Flow rate | 1 | mL/min |

| Temperature | T | Rate | Hold |
|---|---|---|---|
| program | (° C.) | (° C./min) | (min) |
| | 40 | | 5 |
| | 130 | 3 | 0 |
| | 250 | 6 | 0 |
| | 300 | 20 | 1 |

MS conditions
Solvent delay 0.5 min
Scan mode 35 m/z-400 m/z
Method of ionization Electron impact

TABLE 9
concentration of contaminant after decontamination
for samples comprising Con 1 or Con 2 as contaminant

| | | | Initial concen- | Remaining |
|---|---|---|---|---|
| | | | tration of | concentration of |
| | | | Contaminant | Contaminant |
| # | Sample | Bath | Con1 or Con 2 | Con1 or Con 2 |
| 6 | 6 | A | 10 ppm | <1 ppm |
| 7 | 7 | A | 10 ppm | <1 ppm |
| 8 | 8 | A | 10 ppm | <1 ppm |
| 14 | 6 | A′ | 10 ppm | <2 ppm |
| 15 | 7 | A′ | 10 ppm | <2 ppm |
| 16 | 8 | A′ | 10 ppm | <2 ppm |
| 19 | 7 | B | 10 ppm | <2 ppm |
| 22 | 7 | C | 10 ppm | <3 ppm |
| 25 | 7 | D | 10 ppm | <5 ppm |
| 26 | 8 | A | 10 ppm | <5 ppm |
| 27 | 8 | A | 10 ppm | <3 ppm |
| 29 | 6 | F | 10 ppm | <1 ppm |

The results show excellent removal of contaminants from the plastic. The difference between the use of resoiling inhibitors or no resoiling inhibitors is significantly smaller for the contaminants Con 1 and Con 2 than for the coloring agents as contaminants, however still present.

Furthermore, the results show that the decontamination is more efficient for decontamination baths comprising hydrocarbons with lower molecular weight compared to hydrocarbons with higher molecular weight as non-polar organic solvent component.

Furthermore, by treating a plastic article comprising a coloring agent as decontaminant and further a low molecular weight contaminant as further contaminant (sample 8) at low temperature with the decontamination bath, a decontamination of the plastic article from the low molecular weight decontaminant can be achieved without significant decoloration of the plastic article.

Although the present invention has been disclosed in the form of embodiments and variations thereon, it will be understood that numerous additional modifications and variations could be made thereto without departing from the scope of the invention.

For the sake of clarity, it is to be understood that the use of “a” or “an” throughout this application does not exclude a plurality, and “comprising” does not exclude other steps or elements. The mention of a “unit” or a “module” does not preclude the use of more than one unit or module.

1. A decontamination bath for decontaminating plastic articles comprising a contaminant, wherein the decontamination bath comprises:
water,
a non-polar organic solvent component,
optionally an anionic and/or non-ionic surfactant,
a resoiling inhibitor, and
an alkaline agent or an acidic agent for adjusting the pH of the decontamination bath, wherein the amount of the non-polar organic solvent component in the decontamination bath is 0.1 wt % to 25 wt % based on the total weight of the decontamination bath, and
wherein the decontamination bath comprises the alkaline agent and the pH of the decontamination bath is ≥8, or
wherein the decontamination bath comprises the acidic agent and the pH of the decontamination bath is ≤6.

2. The decontamination bath according to claim 1, wherein the non-polar organic solvent component is selected from aromatic non-polar solvents, aliphatic non-polar solvents, and mixtures thereof.

3. The decontamination according to claim 2, wherein the aliphatic non-polar solvent is selected from straight, branched, saturated, unsaturated, and/or cyclic C₅ to C₁₆ aliphatic hydrocarbons.

4. The decontamination bath according to claim 2, wherein the aromatic non-polar solvent is selected from C₁ to C₅-alkyl substituted benzene, C₂-alkyl substituted benzene, Xylol, C₃-alkyl substituted benzene, 1,3,5-trimethylbenzene, 1-ethyl-4-methylbenzene, prop-1-en-2-ylbenzene, propan-2-ylbenzene, propyl benzene, and C₃-alkyl substituted benzene.

5. The decontamination bath according to claim 1, wherein the non-polar organic solvent component comprises straight, branched, saturated, unsaturated, and/or cyclic C₅ to C₁₆ aliphatic hydrocarbons.

6. The decontamination bath according to claim 1, wherein the non-polar organic solvent component comprises straight, branched, saturated, unsaturated and/or cyclic C₇ to C₉ aliphatic hydrocarbons or mixture thereof, or wherein the non-polar organic solvent component is a petroleum fraction having a boiling range of 100° C. to 140° C.

7. The decontamination bath according to claim 1, wherein the decontamination bath comprises the anionic and/or non-ionic surfactant in an amount of 0-01 wt % to 10 wt % based on the total weight of the decontamination bath.

8. The decontamination bath according to claim 1, wherein the non-ionic surfactant is selected from the group comprising aromatic esters, aromatic and non-aromatic carboxylic acid esters, ethyl acrylate, fatty acid esters, alkoxylated, ethoxylated or ethoxylated and propoxylated fatty acid esters, alkoxylated, ethoxylated or ethoxylated and propoxylated fatty acids, poly oxyethylated compounds derived from sorbitol and oleic acid, polysorbate 20, polysorbate 40, polysorbate 60, polysorbate 65, polysorbate 80, polymers that are fatty acid-based with a non-ionic group per molecule, acrylate-copolymers, acrylate/styrene copolymers, fatty acid derivatives, polyalkoxylate, 2-(2-butoxy-ethoxy)ethanol and isotridecanolethoxylate;

9. The decontamination bath according to claim 8, wherein the aromatic ester is selected from benzoic acid benzyl esters, naphthalic acid benzyl esters, phthalic acid benzyl esters and/or isophthalic acid benzyl esters, mixed aromatic aliphatic esters comprising benzyl butyl phthalates, and aliphatic esters comprising benzoic acid butyl esters, phthalic acid dibutyl esters, and/or isophthalic acid dibutyl esters; and benzoic acid benzyl ester, benzoic acid esters such as benzyl benzoate, alkyl benzoates such as methyl or ethyl benzoate, naphthalic acid esters, phthalic acid esters.

10. The decontamination bath according to claim 1, wherein the anionic surfactant is selected from the group comprising alkaline salts of a sulfonic acid, wherein the sulfonic acid is selected from the group comprising alkyl benzenesulfonic acid, alkyl naphtalenesulfonic acid, alkyl phthalic sulfonic acid, isophthalic sulfonic acid benzyl, and a C₉-C₁₃-alkyl benzenesulfonic acid.

11. The decontamination bath according to claim 1, wherein the decontamination bath comprises the resoiling inhibitor in an amount of 0.001 wt % to 10 wt % based on the total weight of the decontamination bath.

12. The decontamination bath according to claim 1, wherein the resoiling inhibitor is selected from the group comprising, polymeric resoiling inhibitors, in particular polyvinylpyrrolidone, derivatives of polyvinylpyrrolidone, such as poly(4-vinylpyridine-N-oxide) and/or polyvinylpyrrolidone-Betaine, copolymers formed of vinylpyrrolidone and vinylimidazole, copolymers formed of vinylpyrrolidone and Poly-4-vinylpyridine-N-oxide, sulfonates comprising an aromatic group, salts of polydiallyldimethylammonium, for example PolyDADMAC, copolymers of polydiallyldimethylammonium formed with acrylic and/or methacrylic acid, copolymers of polydiallyldimethylammonium formed with acrylamide and/or vinylpyrrolidone, saccharide/acrylate copolymers, polycarboxylic acids and copolymers, acrylate copolymers, polymeric carboxylic acid containing polyphosphates, amphiphilc block-copolymers, Polyquaterniums; polyvinylimidazole and copolymers of polyvinylimidazole for example with polyviniylpyrrolidone;
ionic compounds comprising polymeric metasilicate anions such as waterglass;
phosphonates,
dye transfer inhibitors comprising a combination of a) hydrocarbyl substituted pyridine or a polymer or oligomer including vinylpyridine monomer units and b) a hydrocarbyl sulfonic acid such as 2-acrylamido-2-methylpropane sulfonic acid monomer or a polymer formed from the monomer,
surfactant-free colloid systems based on inorganic salts, such as Disodium metasilicate pentahydrate or colloid systems based on phosphates.

13. The decontamination bath according to claim 1, wherein the decontamination bath further comprises an oxidizing agent, selected from the group comprising a peroxide, peroxyacetic acid, hydrogen peroxide, peroxodisulfate, ozone, sodium percarbonate, sodium perborate, sodium percarbonate, m-nitrobenzolsulfonat, H₂SO₄, HNO₃, oxygen-containing anions (oxo anions) of transition metals in high oxidation states such as permanganate MnO₄⁻, KMnO₄, phosphate, oxygen difluoride fluorine, cryptone difluoride, dichromate Cr₂O₇²⁻, metal ions such as Ce₄⁺, noble metal ions such as those of silver and copper, anions of halo-oxygen acids such bromate BrO₃⁻, halogens, such as fluorine, chlorine, bromine and iodine, hypochlorite, sodium hypochlorite, sodium peroxodisulfate and/or potassium hypochlorite.

14. The decontamination bath according to claim 1, wherein the decontamination bath further comprises a reducing agent, selected from the group comprising
hydrogen in combination with precious metal catalyst;
complex hydrides;
phosphorus and sulphur compounds;
sulfinic acid and sulfinic acid derivates; and
glucose mixtures with dispersants.

15. The decontamination bath according to claim 1, wherein the decontamination bath is free of multivalent metal ions.

16. A method for decontaminating a plastic article, wherein the plastic article comprises a contaminant, wherein the contaminant is an organic molecule having a molecular weight Mw≤800 g/mol, comprising:
a) exposing the plastic article to a decontamination bath for ≥1 minute, wherein the decontamination bath has a temperature above a glass transition temperature T_{g} and below a melting temperature Tₘ and/or decomposition temperature of the plastic article and/or wherein the decontamination bath has a temperature ≥60° C. to 130° C.,
and wherein the decontamination bath is realized according to claim 1.

17. The method according to; claim 16, wherein the exposed plastic article does not entirely dissolve in the decontamination bath and/or wherein the plastic article is solid during exposure to the decontamination bath.

18. The method according to claim 16, wherein the contaminant is embedded in the plastic article and/or molecularly solved in the plastic article and/or wherein the contaminant is not covalently bound to a polymer of the plastic article.

19. The method according to claim 16, wherein the contaminant is anon-intentionally added substance and present in the plastic article in a range of 0.00001 wt % to 10 wt % based on the weight of the plastic article.

20. The method according to claim 16, wherein the contaminant is a coloring agent and present in the plastic article in a range of 0.0001 wt % to 10 wt % based on the weight of the plastic article.

21. The method according to claim 16, wherein for the step of exposing the plastic article to the decontamination bath a weight ratio of the contaminant in the plastic article to the resoiling inhibitor is from 1:0.001 to 1:100.000.000 (contaminant:resoiling agent).

22. The method according to claim 16, wherein a weight ratio of the plastic article to the decontamination bath is from 1:1 to 1:100 (plastic article:decontamination bath).

23. The method according to claim 16, wherein the plastic article is an intact plastic article, a plastic granulate and/or plastic powder, or
wherein the method comprises the step of shredding the plastic article to a granulate and/or powder and wherein the step of exposing the plastic article to the decontamination bath comprises exposing the shredded plastic article to the decontamination bath.

24. The method according to claim 16, wherein the granulate and/or powder comprises a mean particle size of 0.1 mm to 50 mm.

25. The method according to claim 16, wherein the method comprises the step of drying the decontaminated plastic article in air.

26. The method according to claim 16, wherein the step of exposing the plastic article to the decontamination bath comprises exposing the plastic article to the decontamination bath at a temperature ≥60° C. to ≤100° C., for ≥1 minute to ≤120 min.

27. The method according to claim 16, wherein the step of exposing the plastic article to the decontamination bath comprises exposing the plastic article to the decontamination bath at a temperature ≥60° C. to ≤100° C., for ≥1 minute to ≤120 min and subsequently exposing the plastic article to the decontamination bath at a temperature ≥80° C. to ≤130° C., for ≥1 minute to ≤120 min.

28. The method according to claim 16, wherein the plastic article is selected from the group comprising a sheet, a foil, a container, a part, a tube, a profile, a rigid packaging such as bottles, jars, caps and closures, color coded packaging and containers of all types, including ones for industrial components, computer face-plates, keyboards, bezels and cellular phones, residential and commercial lighting fixtures and components therefor, such as sheets, used in building and in construction, tableware, including plates, cups and eating utensils, small appliances and their components, optical and sun-wear lenses, and/or wherein the plastic article is a granulate and/or powder from plastic recycling and/or wherein the plastic article is not a textile.
